(19) United States
(12) Patent Application Publication
(10) Pub. No.: US 2013/0084518 A1
(43) Pub. Date: Apr. 4, 2013

(54) NEGATIVE CHEMICAL AMPLIFICATION RESIST COMPOSITION, RESIST FILM, AND, RESIST-COATED MASK BLANKS, METHOD FOR FORMING RESIST PATTERN, AND PHOTOMASK, EACH USING THE SAME

(71) Applicant: FUJIFILM CORPORATION, Tokyo (JP)

(72) Inventors: Tomotaka TSUCHIMURA, Haibara-gun (JP); Takeshi INASAKI, Haibara-gun (JP)

(73) Assignee: FUJIFILM CORPORATION, Tokyo (JP)

(21) Appl. No.: 13/633,681

(22) Filed: Oct. 2, 2012

(30) Foreign Application Priority Data
Oct. 3, 2011 (JP) 2011-219472

(51) Int. Cl. G03F 7/004; G03F 1/00; G03F 1/76; G03F 1/78; G03F 1/50; G03F 7/20

(52) U.S. Cl. 430/5; 430/285.1; 430/283.1; 430/325; 430/296

(57) ABSTRACT

Disclosed is a negative chemical amplification resist composition including (A) a polymer compound having a repeating unit (P) represented by the following formula (I) which is stable in acids and alkalis, and a repeating unit (Q) having a phenolic hydroxyl group; (B) a compound capable of generating an acid when irradiated with actinic rays or a radiation; and (C) a cross-linking agent:

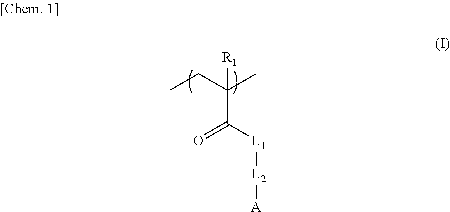

in which, in the formula (I), R₁ represents a hydrogen atom or a methyl group; L₁ represents an oxygen atom or —NH—; L₂ represents a single bond or an alkylene group; and A represents a polycyclic hydrocarbon group.

### BACKGROUND OF THE INVENTION

1. Field of the Invention

The present invention relates to a negative chemical amplification resist composition which is suitably used for ultramicrolithographic processes for the production of ultra-large scale integration (LSI) or high-capacity microchips, or other fabrication processes, and is capable of forming high precision patterns by using an electron beam or extreme ultraviolet rays, as well as a resist film, resist-coated mask blanks, a method for forming a resist pattern, and a photomask, each using the composition. More particularly, the invention relates to a negative chemical amplification resist composition used for a process of using a substrate having a specific underlying layer, and a resist film, resist-coated mask blanks, a method for forming a resist pattern, and a photomask, each using the composition.

2. Description of the Related Art

In microfabrication using a resist composition, along with the increase in the degree of integration of integrated circuits, there is a demand for formation of ultrafine patterns. Therefore, the exposure wavelength also tends to become shorter, as in the case of the transition from g-line to i-line, or further to excimer laser light, and for example, the development of lithographic technologies using electron beams is currently underway. Furthermore, as the resins that are provided for exposure to excimer laser light such as KrF excimer laser light, a resin having a structure in which the hydrogen atom of a phenolic hydroxyl group is substituted by a group having an aliphatic hydrocarbon residue, a resin having a structure in which the hydrogen atom of a phenolic hydroxyl group is substituted by a group having an aryl group, and a resin having a structure in which the hydrogen atom of a phenolic hydroxyl group is substituted by an alkyl group are described in JP 2000-029220 A, JP 3546687 B, and JP 1995-295220 A (JP-H7-295220 A), respectively.

In order to form ultrafine patterns, thickness reduction of the resist is required; however, if a thinner resist is formed, dry etching resistance is decreased. Furthermore, in the field of electron beam lithography, the influence of electron scattering in the resist film (forward scattering) has been reduced in recent years, by increasing the acceleration voltage of the electron beam (EB). However, in that case, the electron energy capture rate of the resist film decreases, sensitivity of the resist film decreases, and the influence of the scattering of electrons reflected on the resist substrate (back scattering) is increased.

In addition, microfabrication using a resist composition is not only used directly in the production of integrated circuits, but is also applied, in recent years, to the preparation of so-called imprint mold structures and the like (for example, JP 2008-162101 A; and Fundamentals and Technological Development and Application Deployment of Nanoimprint—Nanoimprint Substrate Technology and Recent Technology Deployment, edited by Hirai, Yoshihiko, published by Frontier Publishing Co., Ltd. (published in June, 2006)). Accordingly, it is an important task to develop a resist composition which simultaneously satisfies high sensitivity, high resolution (for example, high resolving power, excellent pattern shape, and small line edge roughness (LER)), and satisfactory dry etching resistance, and it is needed to address this problem.

Furthermore, in the case of forming a mask pattern by using a resist composition on a metal oxide film formed on a photomask substrate, scum is likely to be generated on the metal oxide film. Therefore, there is a demand for a resist composition which does not generate any scum irrespective of the type of the substrate.

### SUMMARY OF THE INVENTION

An object of the present invention is to provide a negative chemical amplification resist composition which is capable of forming a pattern that simultaneously satisfies high sensitivity, high resolution (for example, high resolving power, excellent pattern shape, and small line edge roughness (LER)), reduction of scum, and satisfactory dry etching resistance, as well as a resist film, resist-coated mask blanks, a method for forming a resist pattern, and a photomask, each using the resist composition.

The inventors of the present invention conducted a thorough investigation, and as a result, found that the object can be achieved by a negative chemical amplification resist composition containing a polymer compound having a repeating unit of a specific structure.

Specifically, the present invention includes the following.

According to an aspect of the present invention, there is provided a negative chemical amplification resist composition containing (A) a polymer compound including a repeating unit (P) represented by the following formula (I) which is stable in acids and alkalis, and a repeating unit (Q) having a phenolic hydroxyl group; (B) a compound capable of generating an acid when irradiated with actinic rays or a radiation; and (C) a cross-linking agent:

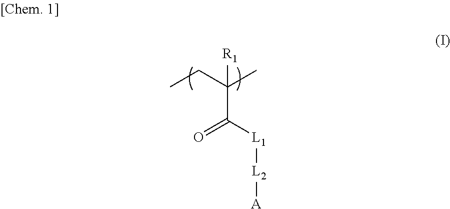

in which, in the formula (I), R₁ represents a hydrogen atom or a methyl group;

L₁ represents an oxygen atom or —NH—,

L₂ represents a single bond or an alkylene group; and

A represents a polycyclic hydrocarbon group.

According to an embodiment of the negative chemical amplification resist composition of the present invention, A in the formula (I) represents an alicyclic polycyclic hydrocarbon group.

According to another embodiment of the negative chemical amplification resist composition of the present invention, the resist composition is intended for use under exposure to an electron beam or extreme ultraviolet rays.

According to another embodiment of the negative chemical amplification resist composition of the present invention, the repeating unit (Q) having a phenolic hydroxyl group is a repeating unit represented by the following formula (IV):

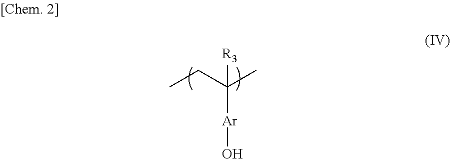

wherein in the formula (IV), R₃ represents a hydrogen atom or a methyl group; and

Ar represents an aromatic ring.

According to another embodiment of the negative chemical amplification resist composition of the present invention, the repeating unit (P) represented by the formula (I) is a repeating unit represented by the following formula (II):

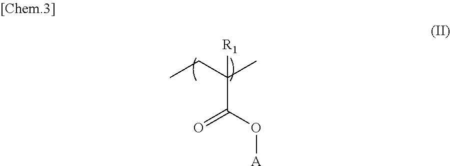

wherein in the formula (II), R₁ and A have the same meanings as R₁ and A defined in the formula (I).

According to another embodiment of the negative chemical amplification resist composition of the present invention, the cross-linking agent (C) is a compound having two or more hydroxymethyl groups or alkoxymethyl groups in the molecule.

According to another embodiment of the negative chemical amplification resist composition of the present invention, the acid generated from the compound (B) by the irradiation of actinic rays or radiation is an acid having a volume size of 130 Å³ or larger.

According to another aspect of the present invention, there is provided a resist film formed from the negative chemical amplification resist composition described above.

According to another aspect of the present invention, there is provided resist-coated mask blanks having the resist film described above.

According to another aspect of the present invention, there is provided a method for forming a resist pattern, the method including exposing the resist film described above, and developing the exposed film.

According to another aspect of the present invention, there is provided a method for forming a resist pattern, the method including exposing the resist-coated mask blanks described above, and developing the exposed mask blanks.

According to an embodiment of the method for forming a resist pattern of the present invention, the exposure is carried out by using an electron beam or extreme ultraviolet rays.

According to another aspect of the present invention, there is provided a photomask which is obtainable by exposing and developing the resist-coated mask blanks described above.

The present invention can provide a negative chemical amplification resist composition which is capable of forming a pattern that simultaneously satisfies high sensitivity, high resolution (for example, high resolving power, excellent pattern shape, and small line edge roughness (LER)), reduction of scum, and satisfactory dry etching resistance, as well as a resist film, resist-coated mask blanks, a method for forming a resist pattern, and a photomask, each using the resist composition.

### DESCRIPTION OF THE PREFERRED EMBODIMENTS

Hereinafter, embodiments of the present invention will be described in detail.

Meanwhile, in regard to the denotation of a group (atomic group) in the present specification, a denotation without specifying whether the group is substituted or unsubstituted implies that the group (atomic group) includes a group (atomic group) having no substituent as well as a group (atomic group) having a substituent. For example, the term “alkyl group” includes not only an alkyl group having no substituent (an unsubstituted alkyl group) but also an alkyl group having a substituent (a substituted alkyl group).

The term “actinic rays” or “radiation” as used in the present invention means, for example, a bright line spectrum of a mercury lamp, far ultraviolet rays represented by excimer laser light, extreme ultraviolet rays (EUV light), X-ray or an electron beam. Also, the term “light” as used in the present invention means actinic rays or radiation. Furthermore, unless stated otherwise, the term “exposure” as used herein includes not only exposure to a mercury lamp, far ultraviolet rays represented by excimer laser light, X-ray, EUV light, or the like, but also rendering with particle beams such as an electron beam and an ion beam. In the present invention, a description of “X to Y” representing a numerical range has a same meaning as “greater than or equal to X and less than or equal to Y”.

The negative chemical amplification resist composition according to the present invention contains (A) a polymer compound having a repeating unit (P) represented by the following formula (I) which is stable in acids and alkalis, and a repeating unit (Q) having a phenolic hydroxyl group; (B) a compound capable of generating an acid when irradiated with actinic rays or a radiation; and (C) a cross-linking agent.

The negative chemical amplification resist composition according to the present invention is preferably intended for the use under exposure to an electron beam or extreme ultraviolet rays.

Hereinafter, the negative chemical amplification resist composition of the present invention will be described in more detail.

[1] (A) Polymer compound

The negative chemical amplification resist composition according to the present invention contains (A) a polymer compound having a repeating unit (P) represented by the following formula (I) which is stable in acids and alkalis, and a repeating unit (Q) having a phenolic hydroxyl group.

In the present invention, as the polymer compound (A) having the repeating units (P) and (Q) is used, the glass transition temperature (Tg) of the polymer compound (A) increases, and a very hard resist film can be formed. Thus, the diffusibility of acid or the dry etching resistance can be controlled. Accordingly, since the diffusibility of acid at the areas exposed to actinic rays or a radiation such as an electron beam or extreme ultraviolet rays is significantly suppressed, the resolving power, pattern shape and LER in fine patterns are excellent. Furthermore, it is thought that the repeating unit (P) having a polycyclic hydrocarbon group in the polymer compound (A) contributes to high dry etching resistance. Also, although the details are not clearly understood, it is speculated that a polycyclic hydrocarbon group has a high hydrogen radical donating property, and serves as a hydrogen source at the time of the degradation of the (B) compound which generates an acid when irradiated with actinic rays or a radiation, which is a photoacid generator, so that the degradation efficiency of the photoacid generator is increased, while the acid generation efficiency is increased. Thus, it is thought that this contributes to excellent sensitivity.

In the repeating unit (P) carried by the polymer compound (A) according to the present invention, a carbonyl group and a polycyclic hydrocarbon group that are linked to the main chain of the polymer compound (A) are linked via a linking group represented by -L₁-L₂- in the formula (I) that will be shown below. As discussed above, it is speculated that since the repeating unit (P) not only contributes to high dry etching resistance, but also can increase the glass transition temperature (Tg) of the polymer compound (A), high resolving power, particularly high resolving power for the formation of fine patterns by an exposure using an electron beam or extreme ultraviolet rays, is provided by the effect of such a combination.

Furthermore, it is contemplated that since the moiety represented by —C(═O)-L₁— (wherein L₁ represents an oxygen atom or —NH—) in the following formula (I) is hydrophilic, hydrophilicity of the resist film in the unexposed areas is improved, and the reduction of scum after development is excellent.

The repeating unit (P) is a repeating unit that is stable in acids and alkalis. A repeating unit that is stable in acids and alkalis means a repeating unit which does not exhibit acid-degradability and alkali-degradability. The term of acid-degradability as used herein means a property by which a compound which generates an acid when irradiated with (B) actinic rays or a radiation undergoes a degradation reaction under the action of the generated acid. Examples of the repeating unit exhibiting acid degradability include conventionally known repeating units having groups that are degraded under the action of acid and generate alkali-soluble groups, which are included in the resins that are used as main components in positive chemical amplification resist compositions.

Furthermore, alkali-degradability means a property of causing a degradation reaction under the action of an alkali developer. Examples of the repeating unit exhibiting alkali-degradability include repeating units having conventionally known groups (for example, groups having a lactone structure) that are degraded under the action of an alkali developer and increases the dissolution rate in the alkali developer, which are included in the resins that are suitably used in positive chemical amplification resist compositions.

The phenolic hydroxyl group according to the present invention means a group obtained by substituting a hydrogen atom of an aromatic group with a hydroxyl group. The aromatic ring of the aromatic group is a monocyclic or polycyclic aromatic ring, and examples thereof include a benzene ring and a naphthalene ring.

Hereinafter, the repeating units (P) and (Q) will be described.

(Repeating unit (P) represented by formula (I) that is stable in acids and alkalis)

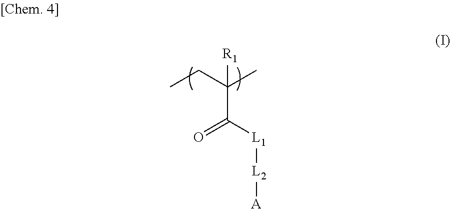

In the formula (I), R₁ represents a hydrogen atom or a methyl group.

L₁ represents an oxygen atom or —NH—.

L₂ represents a single bond or an alkylene group.

A represents a polycyclic hydrocarbon group.

R₁ represents a hydrogen atom or a methyl group, and from the viewpoint of increasing the Tg of the polymer compound (A), R₁ is preferably a methyl group.

L₁ represents an oxygen atom (—O—) or —NH—, and from the viewpoint of sensitivity, L₁ is preferably an oxygen atom (—O—).

L₂ represents a single bond or an alkylene group. The alkylene group represented by L₂ is preferably a linear alkylene group. The carbon number of the alkylene group represented by L₂ is preferably 1 to 10, more preferably 1 to 5, and a methylene group is most preferred.

It is preferable when L₂ represents a single bond, because the Tg of the polymer compound (A) increases.

A represents a polycyclic hydrocarbon group. the polycyclic hydrocarbon group represented by A preferably has a total carbon number of 5 to 40, and more preferably 7 to 30. The polycyclic hydrocarbon group represented by A is preferably an alicyclic polycyclic hydrocarbon group, from the viewpoint of dry etching resistance. Furthermore, the alicyclic polycyclic hydrocarbon group means that the rings that constitute the polycyclic hydrocarbon group are all alicyclic hydrocarbon rings.

According to the present invention, the polycyclic hydrocarbon group means a group having plural monocyclic type hydrocarbon groups, or a polycyclic type hydrocarbon ring group, and may be a bridged ring type.

The monocyclic type hydrocarbon group is preferably a cycloalkyl group having 3 to 8 carbon atoms or an aryl group having 6 to 8 carbon atoms, and examples thereof include a cyclopropyl group, a cyclopentyl group, a cyclohexyl group, a cyclobutyl group, a cyclooctyl group, and a phenyl group. A group having plural monocyclic type hydrocarbon groups has a plural number of these groups. A group having plural monocyclic type hydrocarbon groups preferably has 2 to 4 monocyclic type hydrocarbon groups, and particularly preferably has two monocyclic type hydrocarbon groups.

The polycyclic type hydrocarbon group is a group formed by 2 or more hydrocarbon rings that are condensed, or a bridged type hydrocarbon group formed from 3 or more hydrocarbon rings. It is preferable from the viewpoint of dry etching resistance that the polycyclic type hydrocarbon group is a group formed by 3 or more hydrocarbon rings that are condensed, or a bridged type hydrocarbon group formed from 4 or more hydrocarbon rings. Furthermore, the hydrocarbon ring is preferably an alicyclic hydrocarbon ring from the viewpoint of dry etching resistance, and the alicyclic hydrocarbon ring is preferably a cycloalkane having 3 to 8 carbon atoms. The polycyclic type hydrocarbon group is generally a group formed from 10 or fewer hydrocarbon rings, and preferably a group formed from 6 or fewer hydrocarbon rings. Furthermore, the number of hydrocarbon rings in a polycyclic hydrocarbon group means the number of monocyclic type hydrocarbon rings contained in the polycyclic type hydrocarbon group. For example, a naphthyl group has 2 hydrocarbon rings, an anthracenyl group has 3 hydrocarbon rings, an adamantyl group has 4 hydrocarbon rings, and a tetrahydrodicyclopentadienyl group has 4 hydrocarbon rings.

Examples of the polycyclic type hydrocarbon ring structure in the polycyclic type hydrocarbon ring group include a bicyclic structure, a tricyclic structure and a tetracyclic structure, each having 5 or more carbon atoms, and a polycyclic structure or a polycyclic aromatic group having 6 to 30 carbon atoms is preferred. Examples of the polycyclic type hydrocarbon ring group include an adamantyl group, a decalino group, a norbornyl group, an isoboronyl group, a camphanyl group, an α-pinel group, an androstanyl group, a hexahydroindanyl group, a tetrahydrodicyclopentadienyl group, an indanyl group, a fluorenyl group, an indenyl group, an acenaphthylenyl group, a naphthyl group, and an anthracenyl group.

The polycyclic hydrocarbon group described above is preferably an adamantyl group or a tetrahydrodicyclopentadienyl group from the viewpoint of dry etching resistance, and is most preferably an adamantyl group. The chemical formulae of the polycyclic hydrocarbon structures in these polycyclic hydrocarbon groups are shown below. Furthermore, the polycyclic hydrocarbon group represented by A may be a monovalent group obtained by converting any one hydrogen atom of a polycyclic hydrocarbon structure shown below to a linking bond.

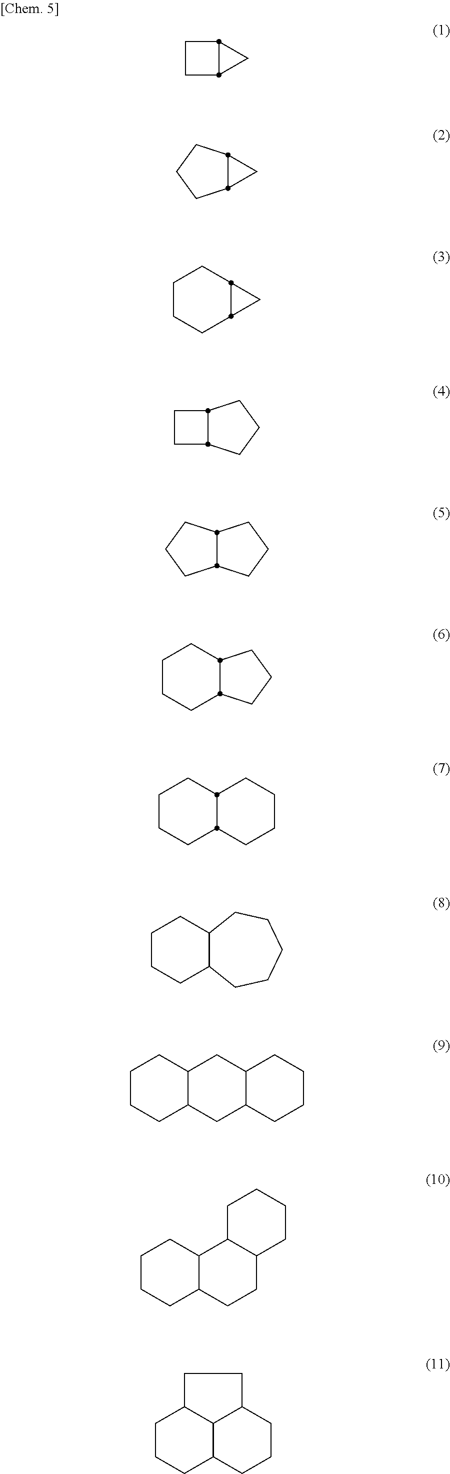

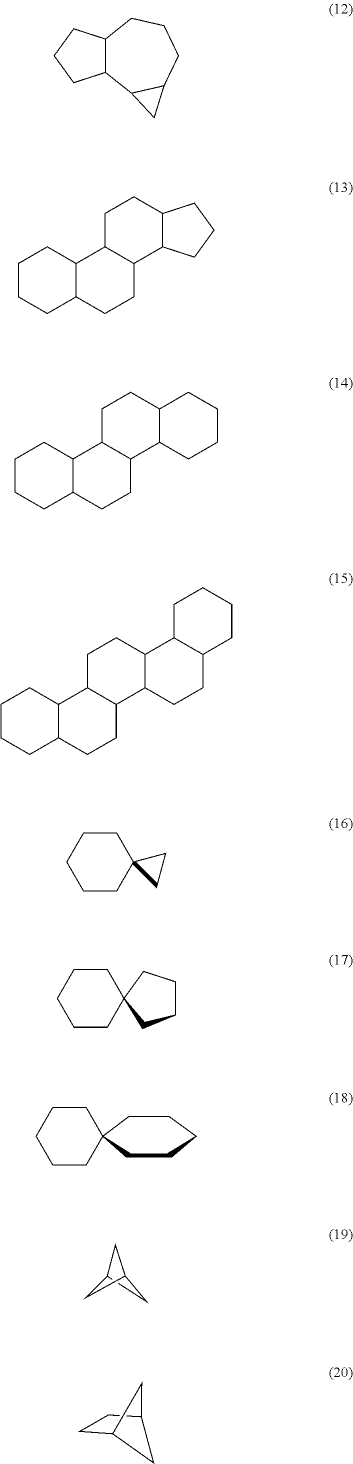

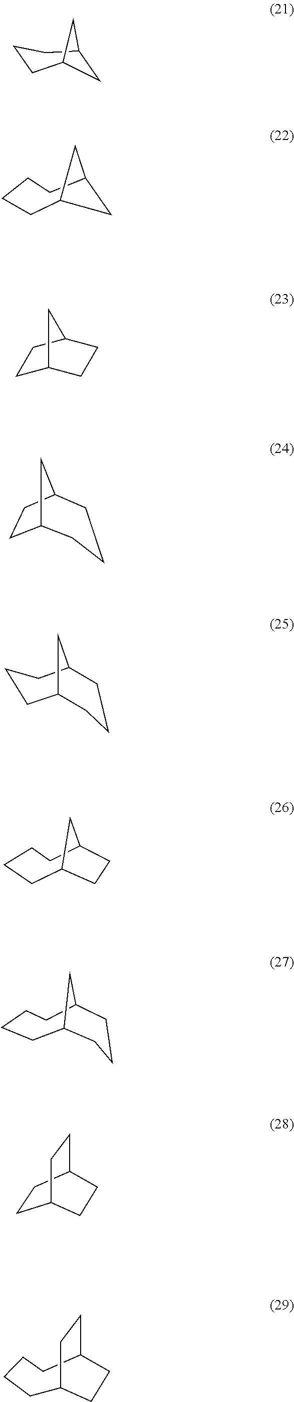

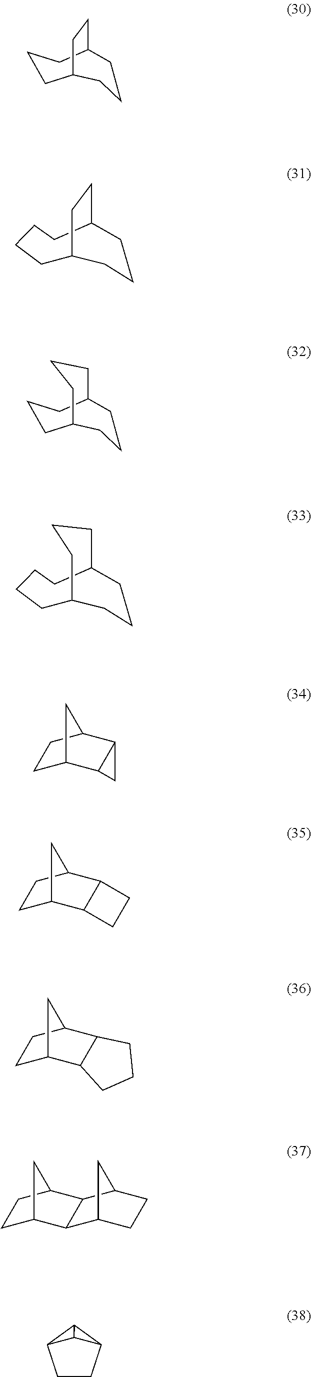

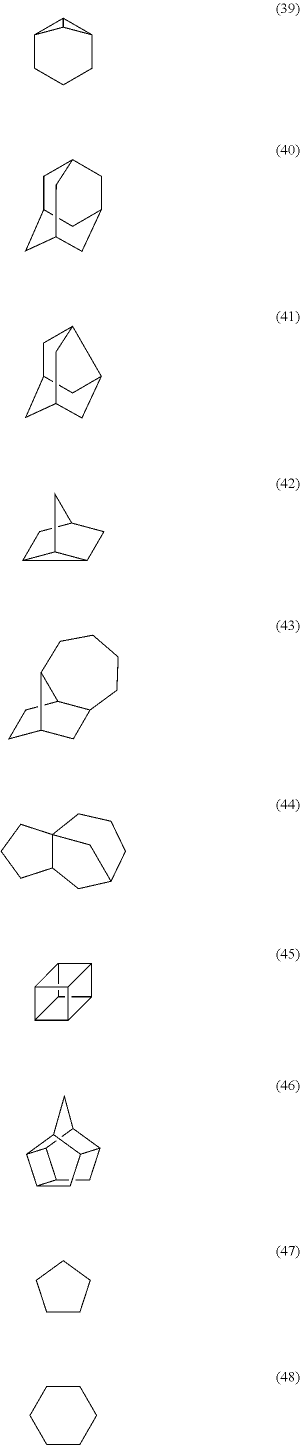

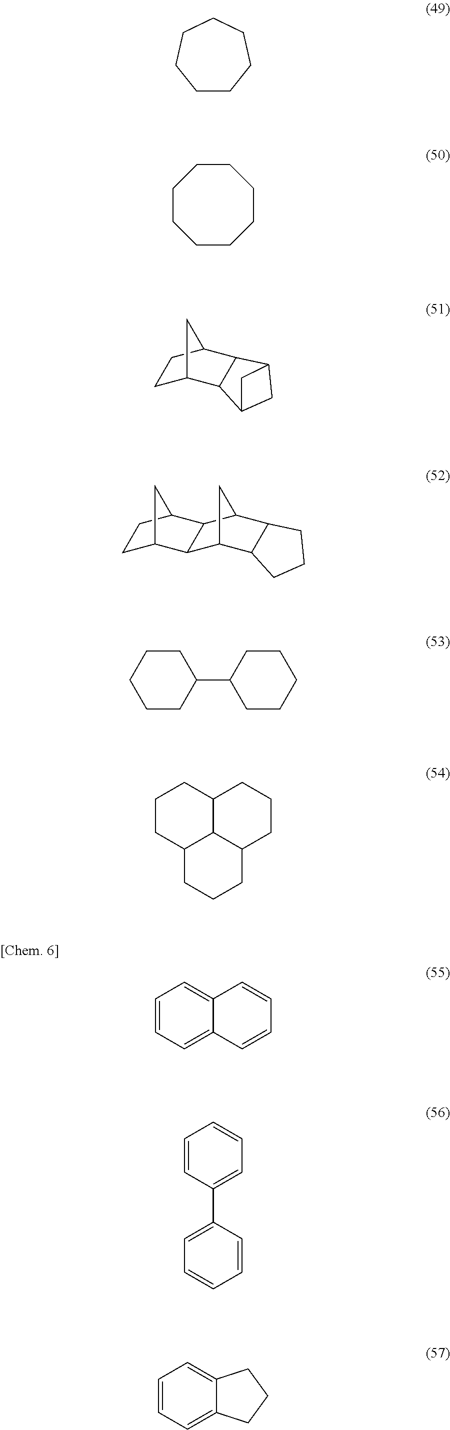

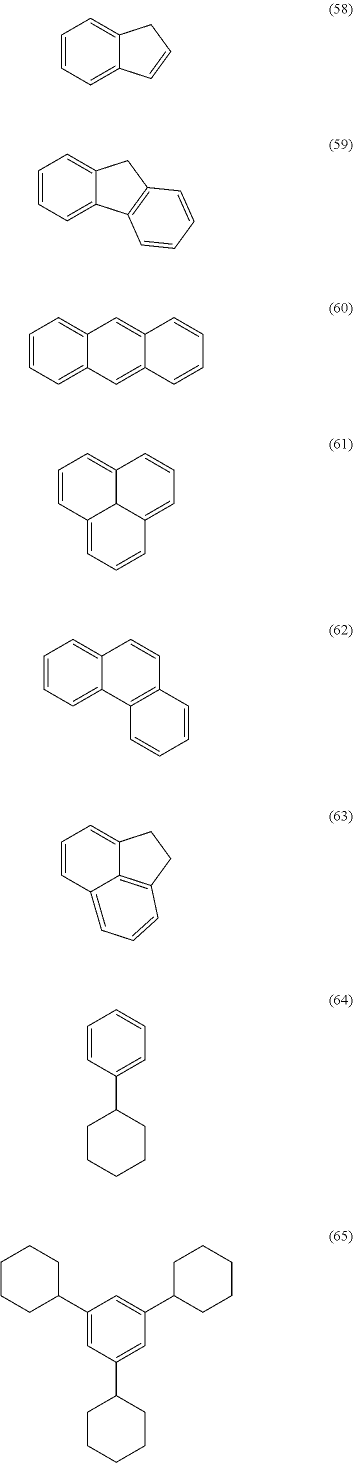

The ring structures may have substituents, and examples of the substituents include an alkyl group (preferably having 1 to 6 carbon atoms), a cycloalkyl group (preferably having 3 to 10 carbon atoms), an aryl group (preferably having 6 to 15 carbon atoms), a halogen atom (preferably a fluorine atom), a hydroxyl group, an alkoxy group (preferably having 1 to 6 carbon atoms), an aryloxy group (preferably having 6 to 15 carbon atoms), a carboxyl group, a carbonyl group, a thiocarbonyl group, an alkoxycarbonyl group (preferably having 2 to 7 carbon atoms), and groups formed by combining these groups (preferably having 1 to 30 carbon atoms in total, and more preferably 1 to 15 carbon atoms in total).

The polycyclic hydrocarbon structure for the polycyclic hydrocarbon group represented by A is preferably a structure represented by any one of the above formulae (6), (7), (23), (36), (37), (40), (51) to (55), (60), (64) and (65), more preferably a structure represented by any one of the above formulae (36), (40), (53), (55) and (60); particularly preferably a structure represented by any one of the above formulae (36) and (40); and most preferably a structure represented by the above formula (40).

The repeating unit (P) represented by the above formula (I) is preferably a repeating unit represented by the following formula (II), in view of enhancing developability.

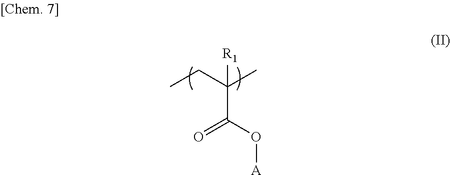

wherein in the formula (II), R₁ represents a hydrogen atom or a methyl group; and

A represents a polycyclic hydrocarbon group.

R₁ and A in the formula (II) have the same meanings as R₁ and A defined in the formula (I), and preferred examples of R₁ and A are also the same as the preferred examples of R₁ and A in the formula (I).

Specific examples of the repeating unit represented by the formula (I) include the following structures.

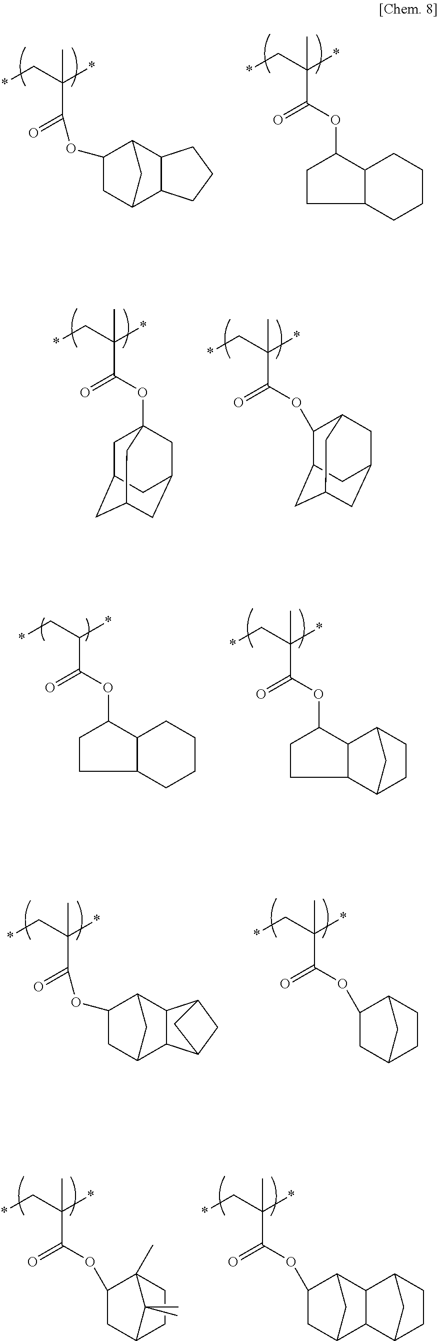

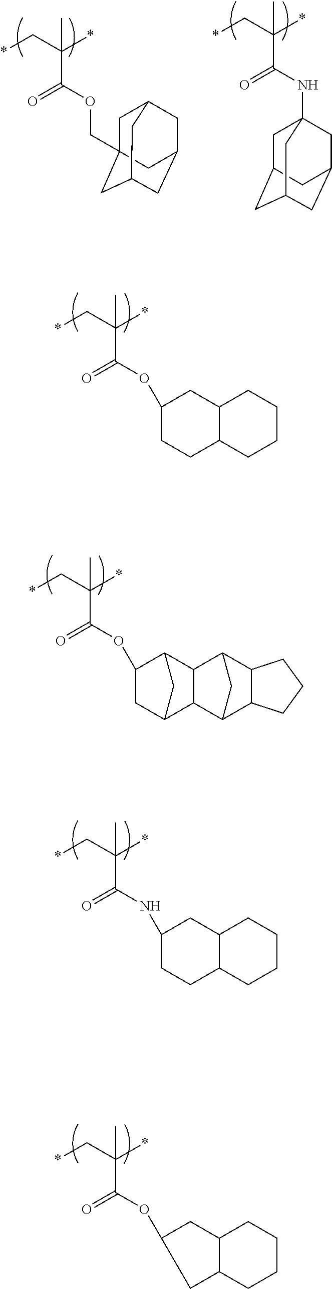

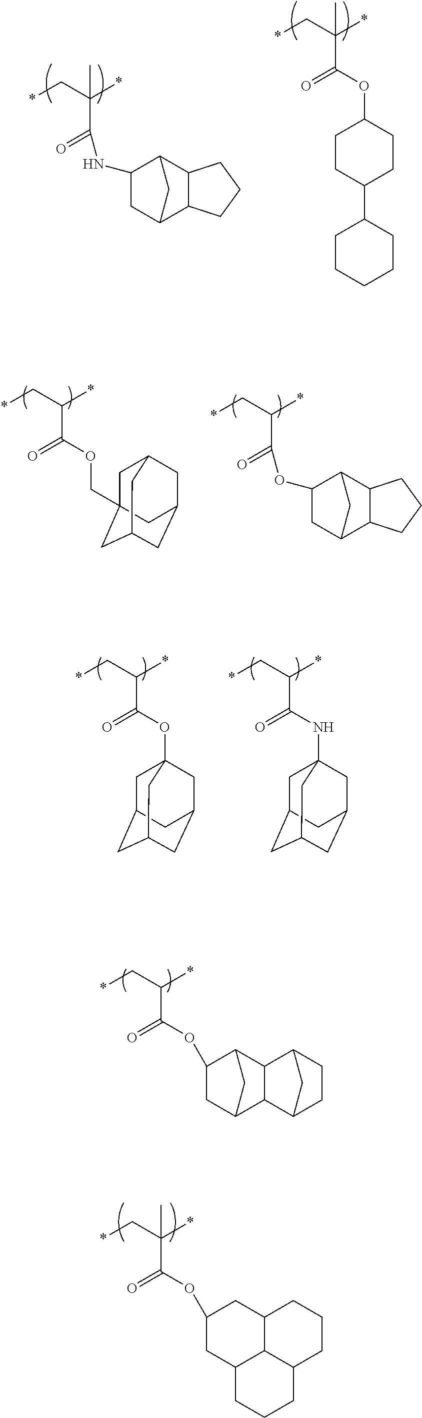

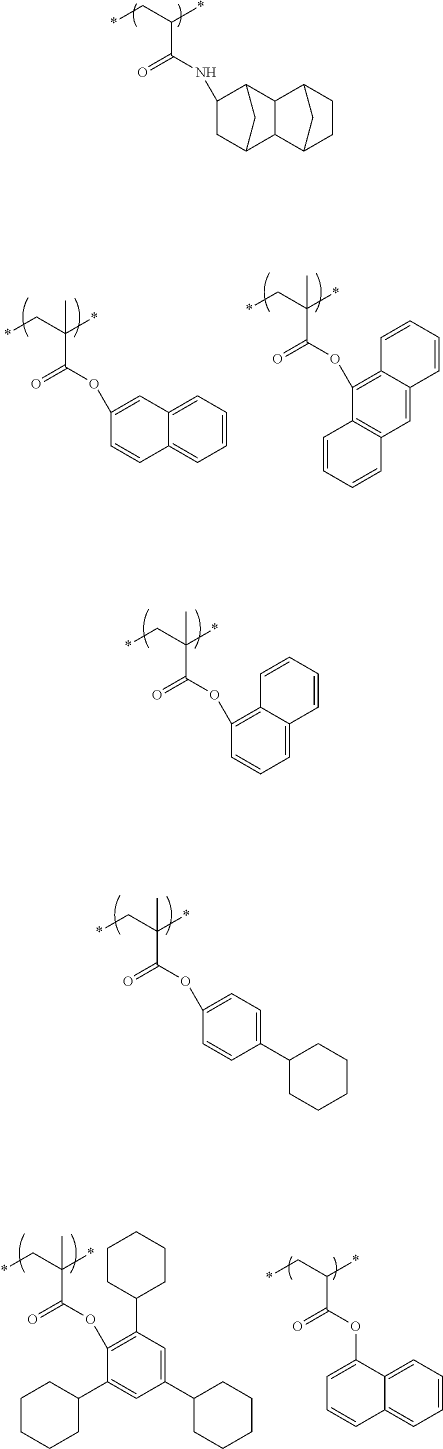

A monomer corresponding to the repeating unit represented by the formula (I) can be synthesized by, for example, a dehydration condensation reaction between an alcohol having a polycyclic hydrocarbon structure and (meth)acrylic acid; or an esterification reaction between an alcohol having a polycyclic hydrocarbon structure and (meth)acrylic acid halide or (meth)acrylic anhydride

The polymer compound (A) of the present invention may have only one kind of the repeating unit represented by the formula (I) as the repeating unit (P), or may have two or more kinds of repeating units represented by the formula (I).

The content of the repeating unit represented by the formula (I) (if there are plural kinds of repeating units, the total content) in the polymer compound (A) of the present invention is preferably in the range of 2 mol % to 50 mol %, more preferably in the range of 3 mol % to 40 mol %, and particularly preferably in the range of 5 mol % to 30 mol %, relative to the total content of the repeating units of the polymer compound (A).

(Repeating Unit (Q) Having Phenolic Hydroxyl Group)

The repeating unit (Q) having a phenolic hydroxyl group is not particularly limited so long as it is a repeating unit having a phenolic hydroxyl group, but is preferably a repeating unit represented by the following formula (III),

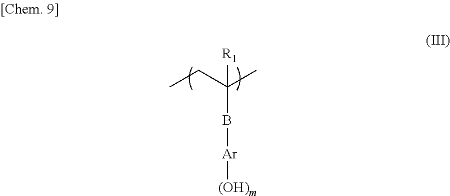

wherein in the formula (III), R₂ represents a hydrogen atom, a methyl group which may be substituted, or a halogen atom;

B represents a single bond or a divalent linking group;

Ar represents an aromatic ring; and

m represents an integer of 1 or greater.

Examples of the methyl group which may be substituted for R₂ include a trifluoromethyl group and a hydroxymethyl group.

R₂ is preferably a hydrogen atom or a methyl group, and a hydrogen atom is preferred from the viewpoint of developability.

The divalent linking group of B is preferably a carbonyl group, an alkylene group (preferably having 1 to 10 carbon atoms, and more preferably 1 to 5 carbon atoms), a sulfonyl group (—S(═O)₂—), —O—, —NH—, and divalent groups combining these.

B preferably represents a single bond, a carbonyloxy group (—C(═O)—O—) or —C(═O)—NH—; and more preferably represents a single bond or a carbonyloxy group (—C(═O)—O—), and it is particularly preferable for B to represent a single bond, from the viewpoint of enhancing dry etching resistance.

The aromatic ring of Ar is a monocyclic or polycyclic aromatic ring, and examples thereof include aromatic hydrocarbon rings having 6 to 18 carbon atoms which may be substituted, such as a benzene ring, a naphthalene ring, an anthracene ring, a fluorene ring, and a phenanthrene ring; and aromatic heterocyclic rings containing heterocyclic rings such as, for example, a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring. Among them, a benzene ring and a naphthalene ring are preferred from the viewpoint of resolution, and a benzene ring is most preferred from the viewpoint of sensitivity.

m is preferably an integer of 1 to 5, and most preferably 1. When m is 1 and Ar is a benzene ring, the position of substitution of —OH may be the para-position, the meta-position or the ortho-position with respect to the bonding position of the benzene ring to B (when B is a single bond, the polymer main chain). However, from the viewpoint of cross-linking reactivity, the para-position and the meta-position are preferred, and the para-position is more preferred.

The aromatic ring of Ar may have a substituent other than the group represented by —OH, and examples of the substituent include an alkyl group, a halogen atom, a hydroxyl group, an alkoxy group, a carboxyl group, an alkoxycarbonyl group, an alkylcarbonyl group, an alkylcarbonyloxy group, an alkylsulfonyloxy group, and an arylcarbonyl group.

The repeating unit (Q) having a phenolic hydroxyl group is more preferably a repeating unit represented by the following formula (IV), from the viewpoints of cross-linking reactivity, developability, and dry etching resistance.

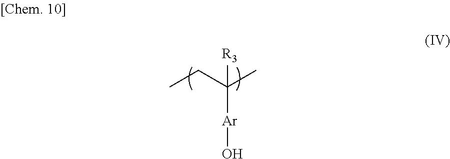

wherein in the formula (IV), R₃ represents a hydrogen atom or a methyl group; and

Ar represents an aromatic ring.

R₃ represents a hydrogen atom or a methyl group, and R₃ is preferably a hydrogen atom in view of developability,

Ar in the formula (IV) has the same meaning as Ar in the formula (III), and preferred examples of Ar are also the same as the preferred examples of Ar in the formula (III). The repeating unit represented by the formula (IV) is preferably a repeating unit derived from hydroxystyrene (that is, a repeating unit represented by the formula (IV), wherein R₃ represents a hydrogen atom; and Ar represents a benzene ring), from the viewpoint of sensitivity.

The content of the repeating unit (Q) having a phenolic hydroxyl group is preferably 10 mol % to 98 mol %, more preferably 30 mol % to 97 mol %, and even more preferably 40 mol % to 95 mol %, relative to the total content of the repeating units of the polymer compound (A). Thereby, particularly in the case where the resist film is a thin film (for example, when the thickness of the resist film is 10 nm to 150 nm), the dissolution rate of the exposed areas in the resist film of the present invention formed by using the polymer compound (A) in an alkali developer can be more securely decreased (that is, the dissolution rate of the resist film using the polymer compound (A) can be more reliably controlled to be optimal). As a result, the sensitivity can be more reliably increased.

Examples of the repeating unit (Q) having a phenolic hydroxyl group will be described below, but the examples are not intended to be limited to these.

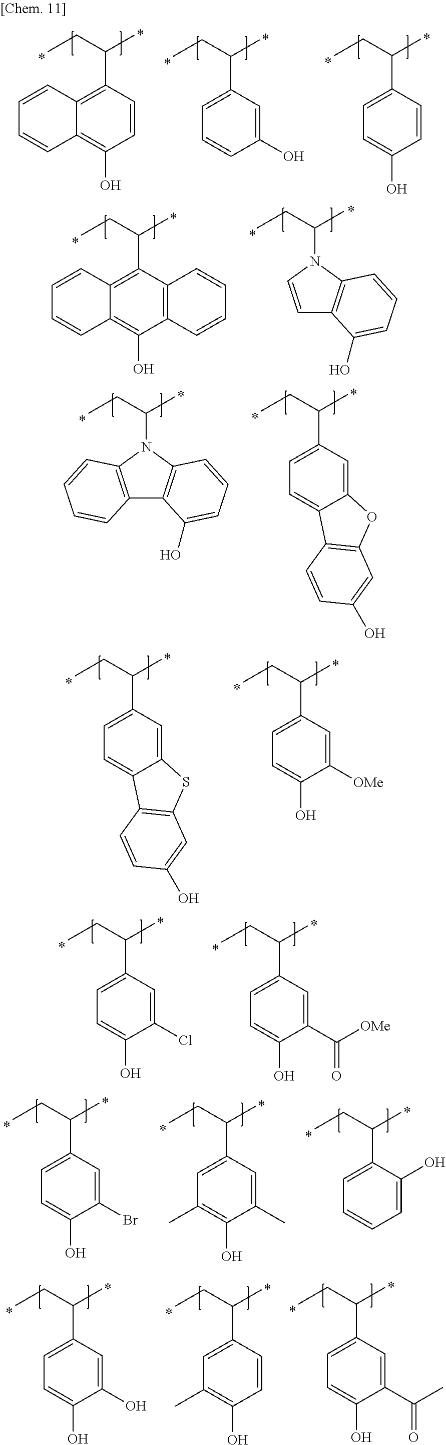

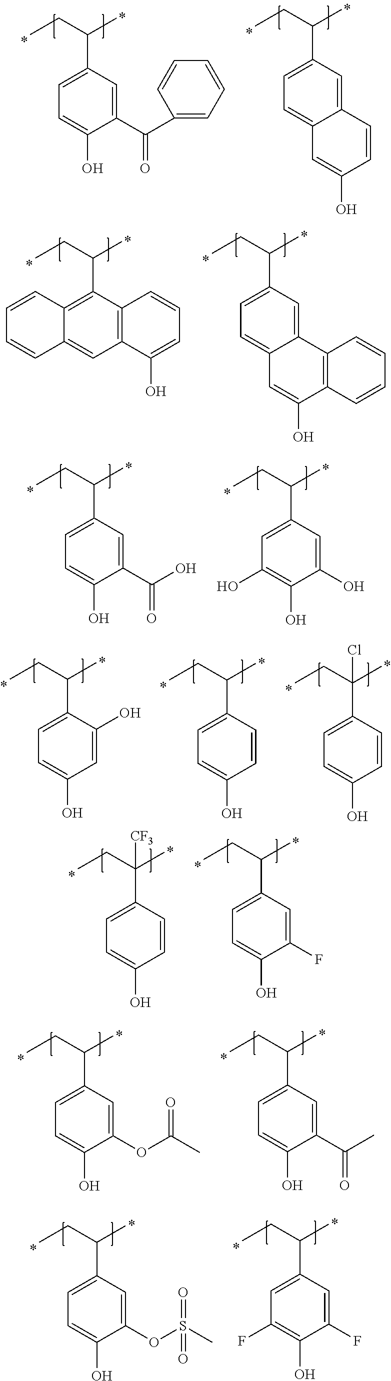

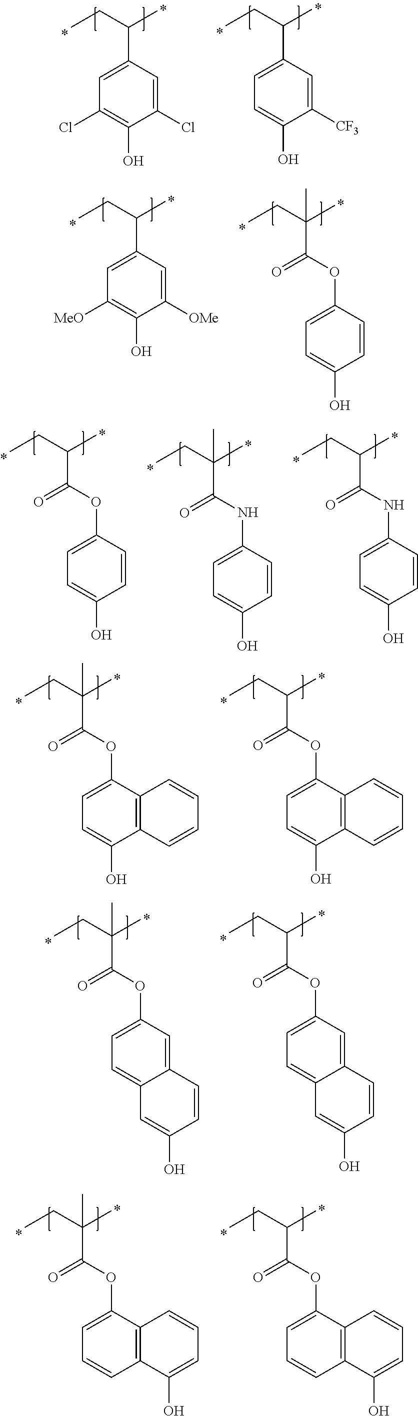

The polymer compound (A) used in the present invention preferably has the following repeating units (hereinafter, also referred to as “other repeating units”) as repeating units other than the repeating units described above.

Examples of a polymerizable monomer for forming these other repeating units include styrene, an alkyl-substituted styrene, an alkoxy-substituted styrene, an O-alkylated styrene, an O-acylated styrene, hydrogenated hydroxystyrene, maleic anhydride, an acrylic acid derivative (acrylic acid, an acrylic acid ester, or the like), a methacrylic acid derivative (methacrylic acid, a methacrylic acid derivative, or the like), an N-substituted maleimide, acrylonitrile, methacrylonitrile, vinylnaphthalene, vinylanthracene, and indene which may be substituted.

The polymer compound (A) may not contain these other repeating units; however, if the polymer compound contains the other repeating units, the content of these other repeating units in the polymer compound (A) is generally 1 mol % to 20 mol %, and preferably 2 mol % to 10 mol %, relative to the total content of the repeating units that constitute the polymer compound (A).

Furthermore, it is also preferable that the polymer compound (A) further have a repeating unit having a group which is degraded under the action of an alkali developer and increases the dissolution rate in the alkali developer, or a repeating unit having a photoacid generating group, as the repeating unit other than the repeating units described above.

Examples of the repeating unit having a group which is degraded under the action of an alkali developer and increases the dissolution rate in the alkali developer, include repeating units having a lactone structure and a phenyl ester structure. The repeating unit is preferably a repeating unit having a 5 to 7-membered ring lactone structure, and more preferably a repeating unit having a structure in which another ring structure is condensed with a 5 to 7-membered ring lactone structure to form a bicyclo structure or a spiro structure. Specific examples of the repeating unit having a group which is degraded under the action of an alkali developer and increases the dissolution rate in the alkali developer will be shown below. In the formulae, Rx represents H, CH₃, CH₂OH or CF₃.

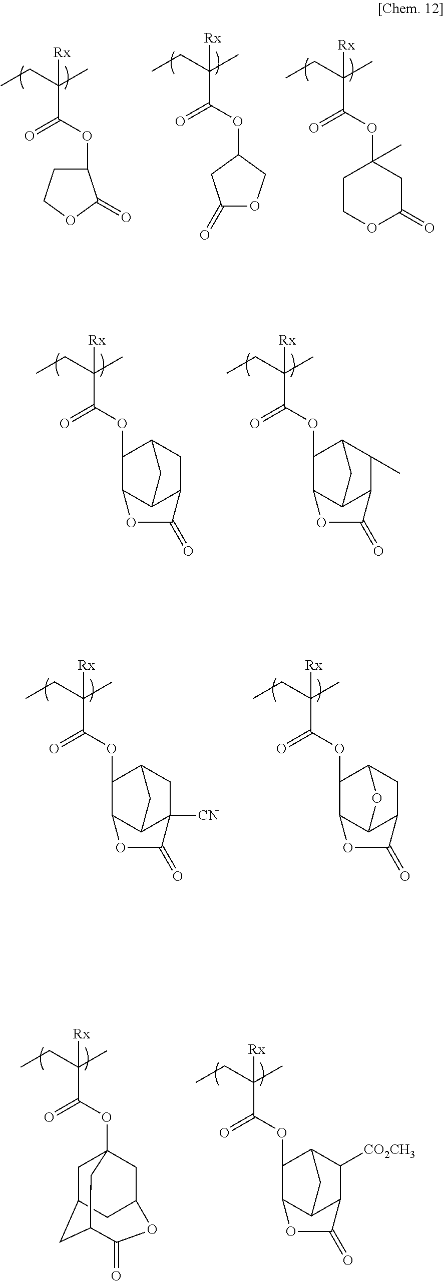

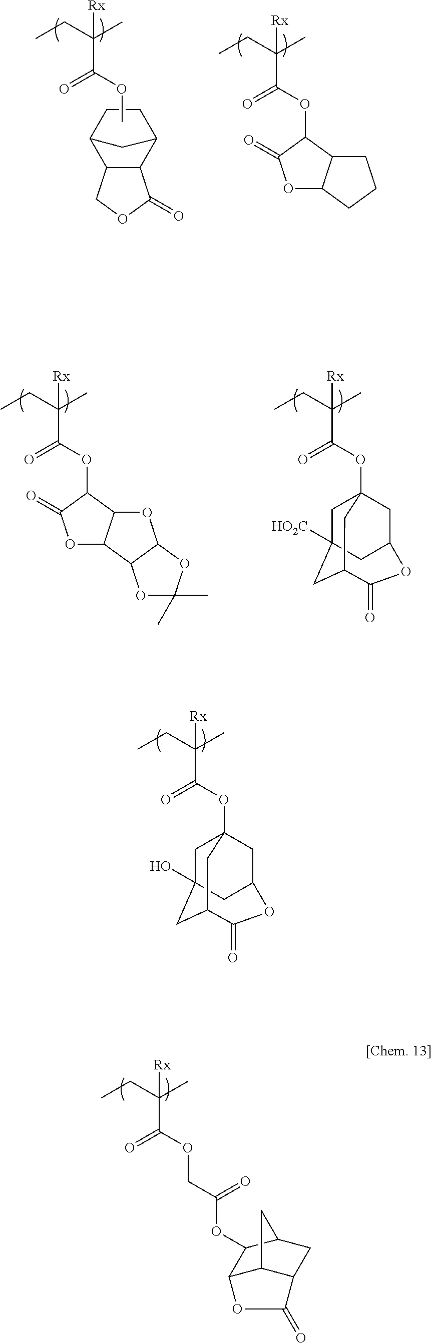

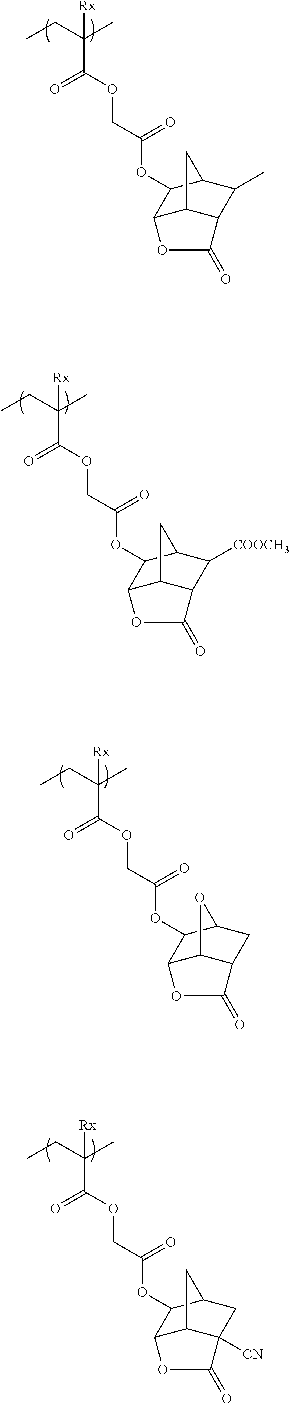

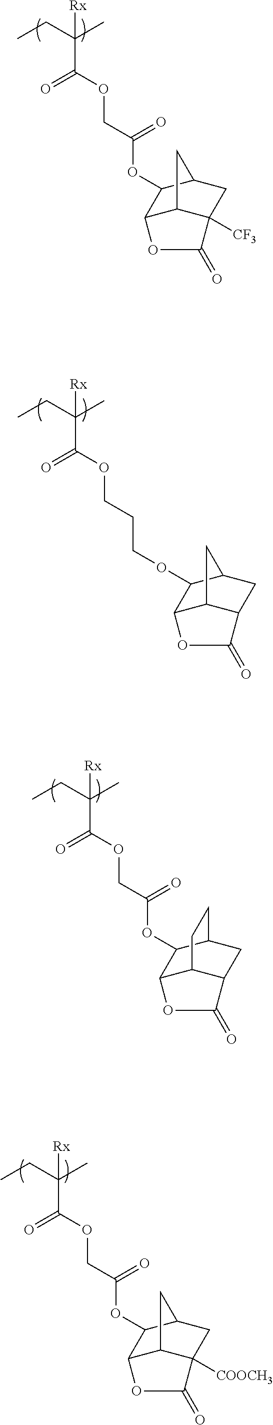

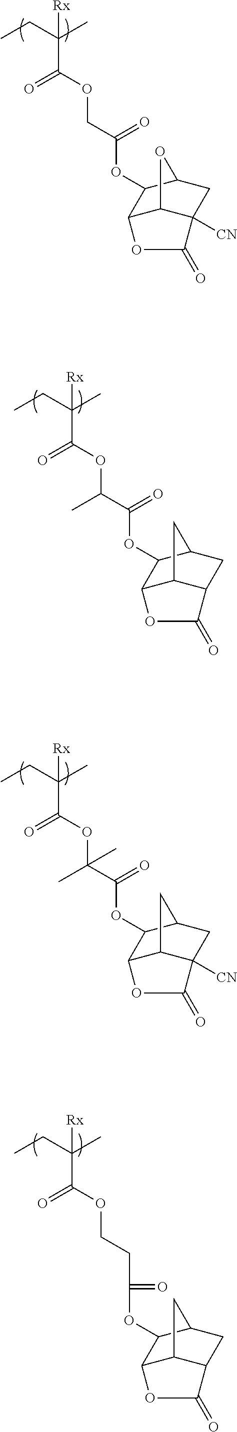

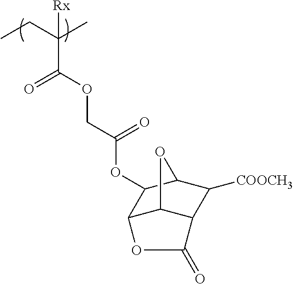

The polymer compound (A) may not contain the repeating unit having a group which is degraded under the action of an alkali developer and increases the dissolution rate in the alkali developer; however, if the polymer compound (A) contains the repeating unit, the content of the repeating unit having a group which is degraded by the action of an alkali developer and increases the dissolution rate in the alkali developer is preferably 1 mol % to 20 mol %, more preferably 2 mol % to 10 mol %, and even more preferably 3 mol % to 5 mol %, relative to the total content of the repeating units in the polymer compound (A).

According to the present invention, the polymer compound (A) can further contain a repeating unit having a photoacid generating group as a repeating unit other than those described above. Examples of such a unit include the repeating units described in paragraph of JP 1997-325497 A (JP-H9-325497 A); and repeating units described in paragraphs [0038] to [0041] of JP 2009-093137 A. In this case, it is thought that this repeating unit having a photoacid generating group corresponds to the compound of the present invention that generates an acid when irradiated with actinic rays or a radiation.

Specific examples of monomers corresponding to the repeating unit having a photoacid generating group (expressed in the structure of the acid generated by exposure to EB or EUV) are shown below.

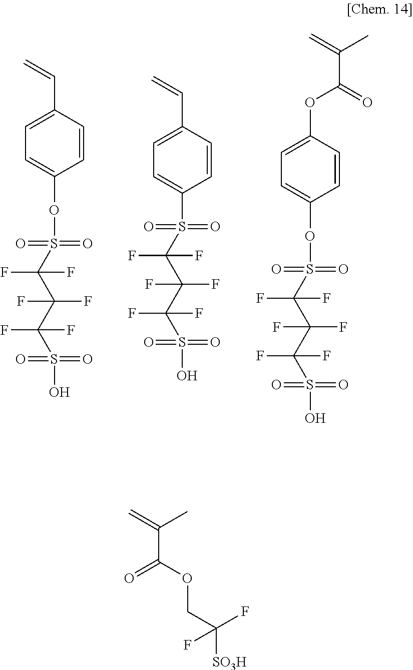

When the polymer compound contains the repeating unit having a photoacid generating group, the content of the repeating unit having a photoacid generator is preferably 1 mol % to 40 mol %, more preferably 5 mol % to 35 mol %, and even more preferably 5 mol % to 30 mol %, relative to the total content of the repeating units in the polymer compound (A).

The polymer compound (A) can be synthesized by a known radical polymerization method, a known anion polymerization method, or a living radical polymerization method (iniferter method or the like). For example, in the anion polymerization method, a polymer can be obtained by dissolving a vinyl monomer in an appropriate organic solvent, and causing the vinyl monomer to react, usually under cooling conditions, by using a metal compound (butyllithium or the like) as an initiator.

As the polymer compound (A), a polyphenol compound produced by a condensation reaction between an aromatic ketone or an aromatic aldehyde, and a compound containing 1 to 3 phenolic hydroxyl groups (for example, JP 2008-145539 A), a calixarene derivative (for example, JP 2004-018421 A), a Noria derivative (for example, JP 2009-222920 A), a polyphenol derivative (for example, JP 2008-094782 A) can also be applied, and the polymer compound (A) may also be synthesized by modifying these compounds by polymer reactions.

Furthermore, the polymer compound (A) is preferably synthesized by modifying a polymer synthesized by a radical polymerization method or an anion polymerization method, by a polymer reaction.

The weight average molecular weight of the polymer compound (A) is preferably 1,000 to 200,000, more preferably 2,000 to 50,000, and even more preferably 2,000 to 10,000.

The dispersity (molecular weight distribution) (Mw/Mn) of the polymer compound (A) is preferably 2.0 or less, and from the viewpoint of enhancing sensitivity and resolution, the dispersity is more preferably 1.0 to 1.80, and most preferably 1.0 to 1.60. When living polymerization such as living anion polymerization is used, the dispersity (molecular weight distribution) of the polymer compound thus obtained becomes uniform, which is preferable. The weight average molecular weight and dispersity of the polymer compound (A) are defined by the values obtained by gas permeation chromatography (GPC) measurement and calculated relative to polystyrene standards. According to the present specification, the weight average molecular weight (Mw) and number average molecular weight (Mn) of the polymer compound (A) can be determined by using, for example, HLC-8120 (manufactured by Tosoh Corp.) and using a TSK gel Multipore HXL-M (manufactured by Tosoh Corp., 7.8 mm ID×30.0 cm) as a column and tetrahydrofuran (THF) as an eluent.

Furthermore, the polymer compound (A) is not limited to compounds that are obtainable by polymerizing monomers that correspond to the specific repeating units described above, and a relatively low molecular weight compound such as a molecular resist can also be used so long as the low molecular weight compound contains a polycyclic hydrocarbon group and has a structure represented by —C(═O)-L₁-L₂-A in the formula (I).

The amount of the polymer compound (A) added to the chemical amplification resist composition of the present invention is preferably 30 mass % to 95 mass %, more preferably 40 mass % to 90 mass %, and particularly preferably 50 mass % to 85 mass %, relative to the total solids content of the composition.

Specific examples of the polymer compound (A) will be shown below, but the present invention is not intended to be limited to these.

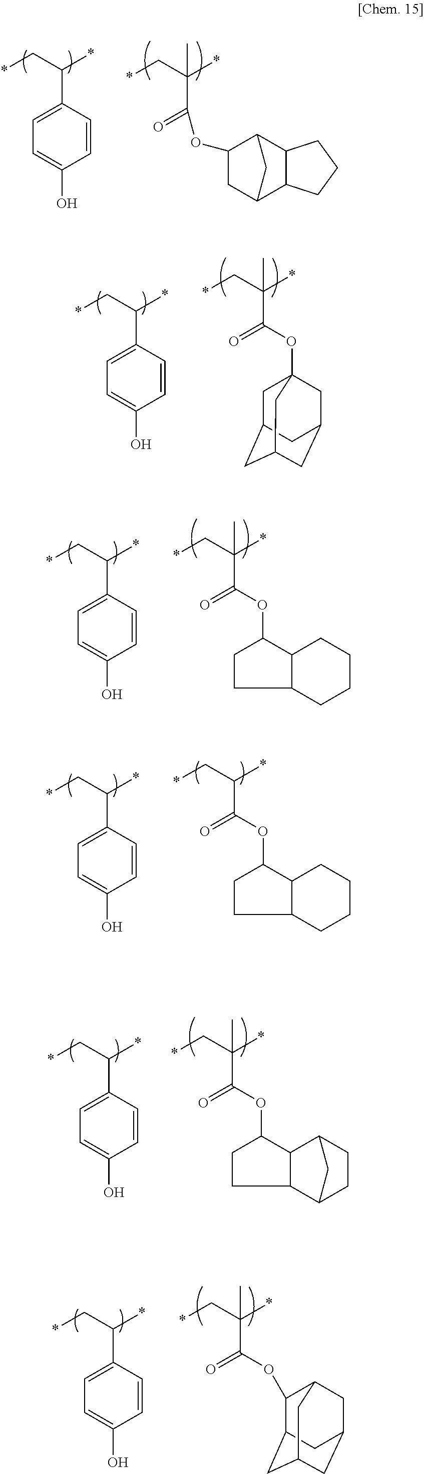

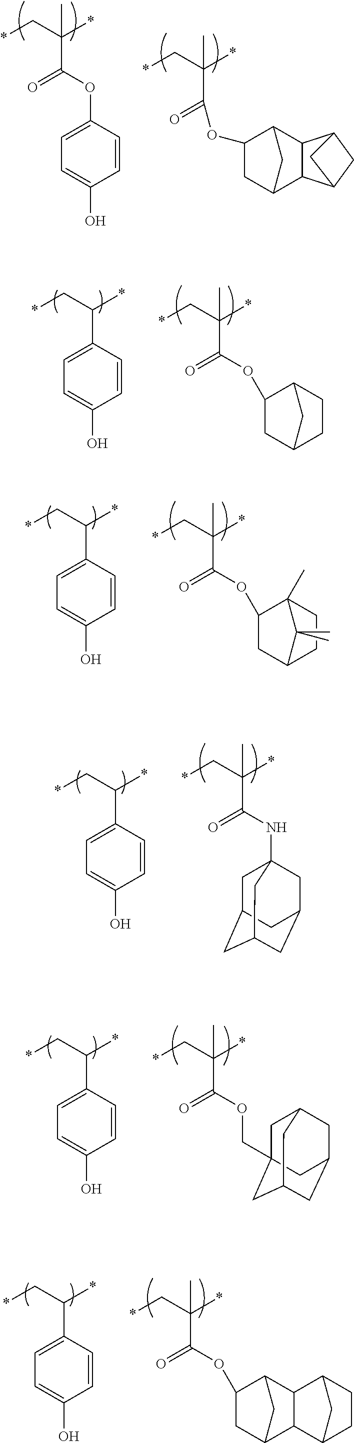

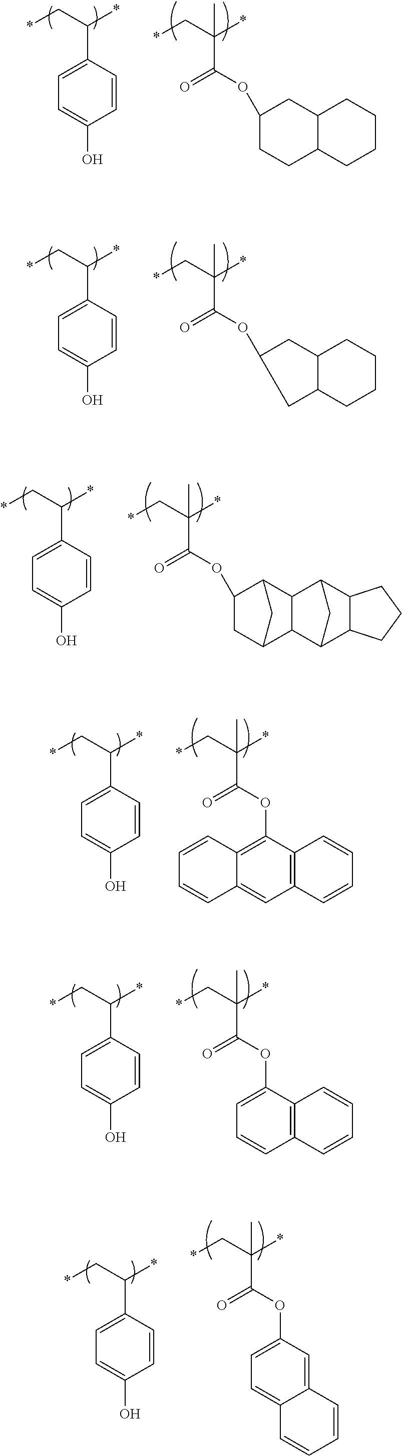

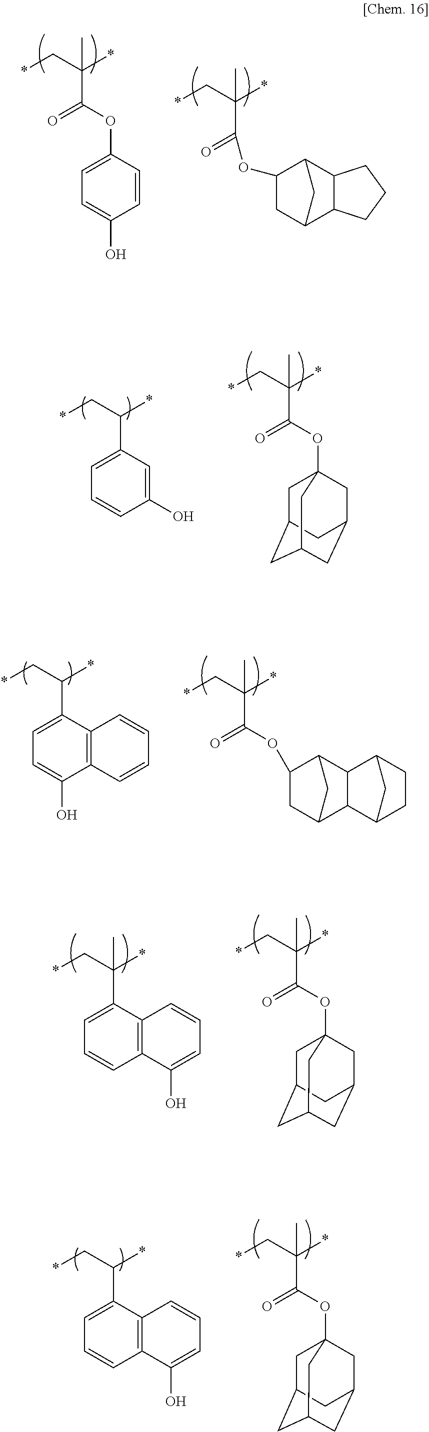

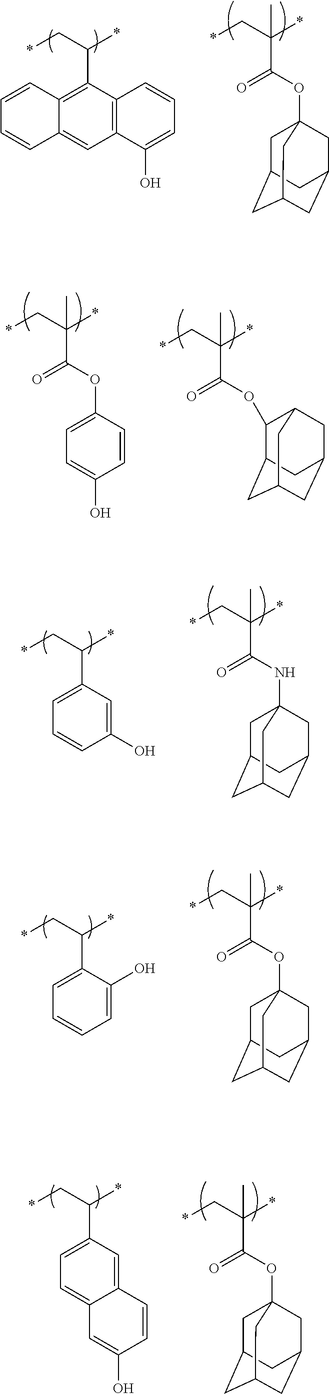

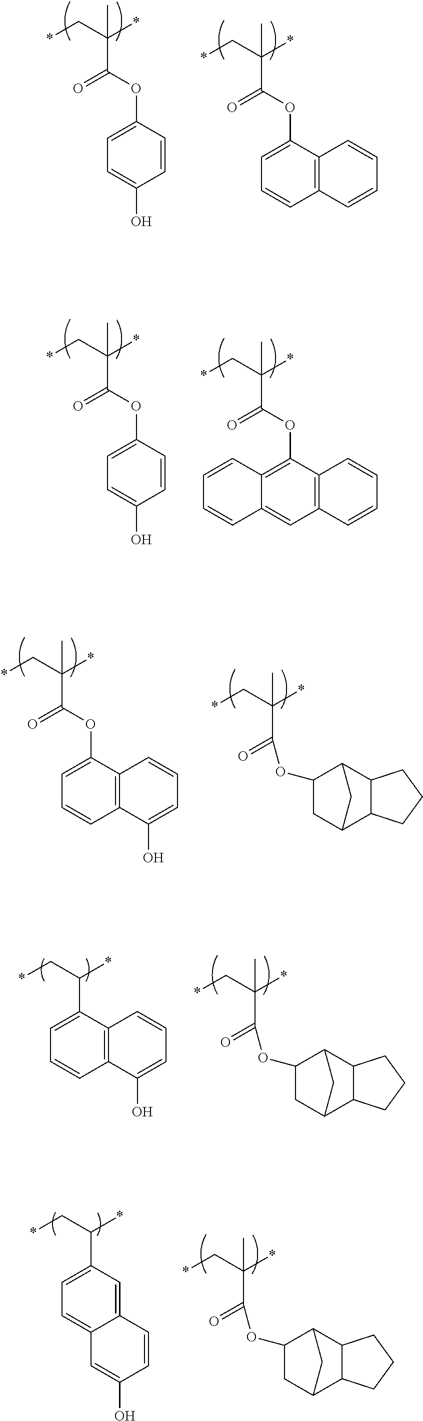

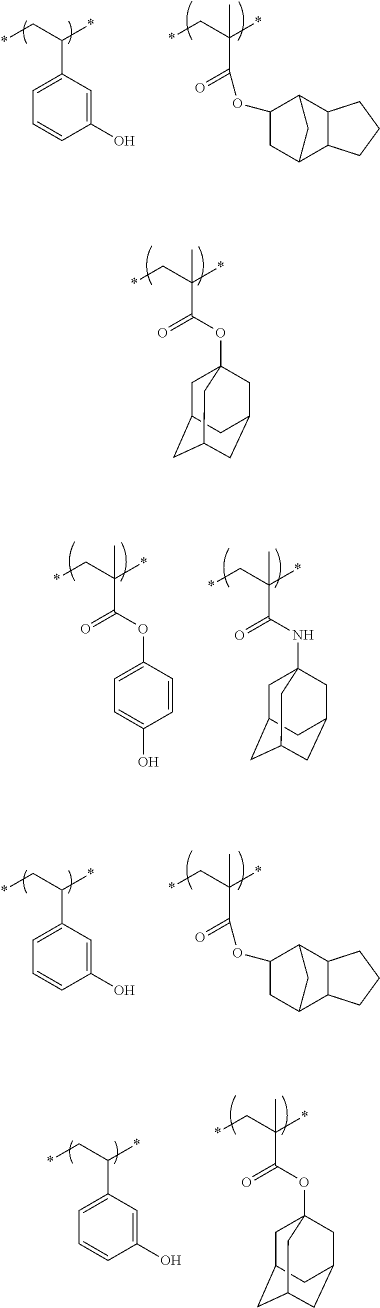

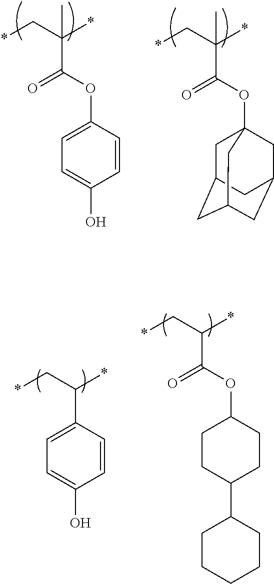

[2] Compound that Generates Acid when Irradiated with Actinic Rays or Radiation

The negative chemical amplification resist composition of the present invention contains a compound (B) that generates an acid when irradiated with actinic rays or a radiation (hereinafter, such a compound is appropriately simply referred to as an “acid generator (B)”).

A preferred form of the acid generator (B) may be an onium compound. Examples of such an onium compound include a sulfonium salt, an iodonium salt, and a phosphonium salt.

Furthermore, another preferred form of the acid generator (B) may be a compound capable of generating sulfonic acid, imide acid or a methide acid when irradiated with actinic rays or radiation. Examples of the acid generator in that form include a sulfonium salt, an iodonium salt, a phosphonium salt, an oxime sulfonate, and an imide sulfonate.

The acid generator (B) used in the present invention is not limited to low molecular weight compounds, and a compound in which a group which generates an acid when irradiated with actinic rays or a radiation is introduced into the main chain or a side chain of a polymer compound, can also be used. Furthermore, as discussed above, when a group which generates an acid when irradiated with actinic rays or radiation is present in a repeating unit which serves as a copolymerization component of the polymer compound (A) used in the present invention, an acid generator (B) of a different molecule from the polymer compound of the present invention may be absent.

The acid generator (B) is preferably a compound capable of generating an acid when irradiated with an electron beam or extreme ultraviolet rays.

Preferred examples of the onium compound include a sulfonium compound represented by the following formula (1) and an iodonium compound represented by the following formula (2).

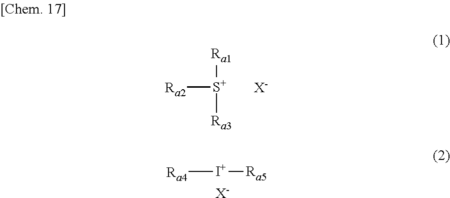

wherein in the formulae (1) and (2),

Rₐ₁, Rₐ₂, Rₐ₃, Rₐ₄ and Rₐ₅ each independently represent an organic group; and

X⁻ represents an organic anion.

Hereinafter, the sulfonium compound represented by the formula (1) and the iodonium compound represented by the formula (2) will be described in more detail.

Rₐ₁ to Rₐ₃ of the formula (1) and Rₐ₄ and Rₐ₅ of the formula (2) each independently represent an organic group, but preferably, at least one of Rₐ₁ to Rₐ₃ and at least one of Rₐ₄ and Rₐ₅ are respectively an aryl group. The aryl group is preferably a phenyl group and a naphthyl group, and more preferably a phenyl group.

Examples of the organic anion of X⁻ in the formulae (1) and (2) include a sulfonate anion, a carboxylate anion, a bis(alkylsulfonyl)amide anion, and a tris(alkylsulfonyl)methide anion. The organic anion is preferably represented by the following formula (3), (4) or (5), and more preferably represented by the following formula (3).

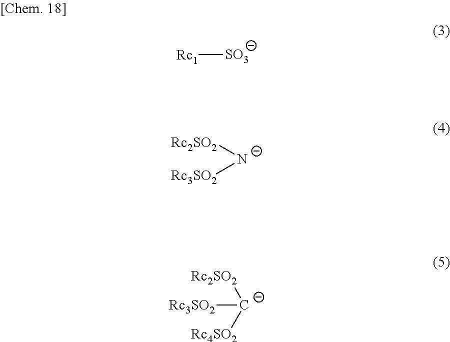

in which, in the formulae (3), (4) and (5), R_{c1}, R_{c2}, R_{c3} and R_{c4} respectively represent an organic group.

The organic anion of X⁻ corresponds to the sulfonic acid, imide acid or methide acid, which are acids generated by irradiation of actinic rays or a radiation such as an electron beam or extreme ultraviolet rays.

Examples of the organic group of R_{c1} to R_{c4} include an alkyl group, a cycloalkyl group, an aryl group, and groups having a plural number of these groups linked together. Among these organic groups, more preferred examples include an alkyl group in which the 1-position is substituted with a fluorine atom or a fluoroalkyl group; a cycloalkyl group substituted with a fluorine atom or a fluoroalkyl group; and a phenyl group substituted with a fluorine atom or a fluoroalkyl group. A plural number of the organic groups of R_{c2} to R_{c4} may be joined together to form a ring, and the group in which a plural number of these organic groups are joined is preferably an alkylene group substituted with a fluorine atom or a fluoroalkyl group. When the organic group has a fluorine atom or a fluoroalkyl group, the acidity of the acid generated by light irradiation increases, and sensitivity is enhanced. However, it is preferable that terminal groups do not contain fluorine atoms as the substituent.

From the viewpoint of suppressing the diffusion of the acid generated by light exposure to unexposed areas and thereby making the resolution or pattern shape satisfactory, the compound (B) that generates an acid is preferably a compound which generates an acid (more preferably, sulfonic acid) having a volume size of 130 A³ or greater; more preferably a compound which generates an acid (more preferably, sulfonic acid) having a volume size of 190 A³ or greater; even more preferably a compound which generates an acid (more preferably, sulfonic acid) having a volume size of 230 A³ or greater; particularly preferably a compound which generates an acid (more preferably, sulfonic acid) having a volume size of 270 A³ or greater; and particularly preferably a compound which generates an acid (more preferably, sulfonic acid) having a volume size of 400 A³ or greater. However, from the viewpoints of sensitivity and coating solvent solubility, the volume is preferably 2000 A³ or less, and more preferably 1500 A³ or less. The value of the volume was determined by using “WinMOPAC” manufactured by Fujitsu, Ltd. That is, first, the chemical structure of the acid related to each example is input, subsequently the most stable configuration of each acid is determined by calculation of the molecular force field using an MM3 method by using the chemical structure as the initial structure, and then molecular orbit calculation is carried out by using a PM3 method with respect to this most stable configuration. Thereby, the “accessible volume” of each acid can be calculated.

Particularly preferred examples of the acid generator (B) will be shown below. Meanwhile, for some of the examples, the calculated values of volume are indicated together (unit: Å³). Meanwhile, the calculated value determined herein is the volume value of an acid with a proton bonded to the anion moiety.

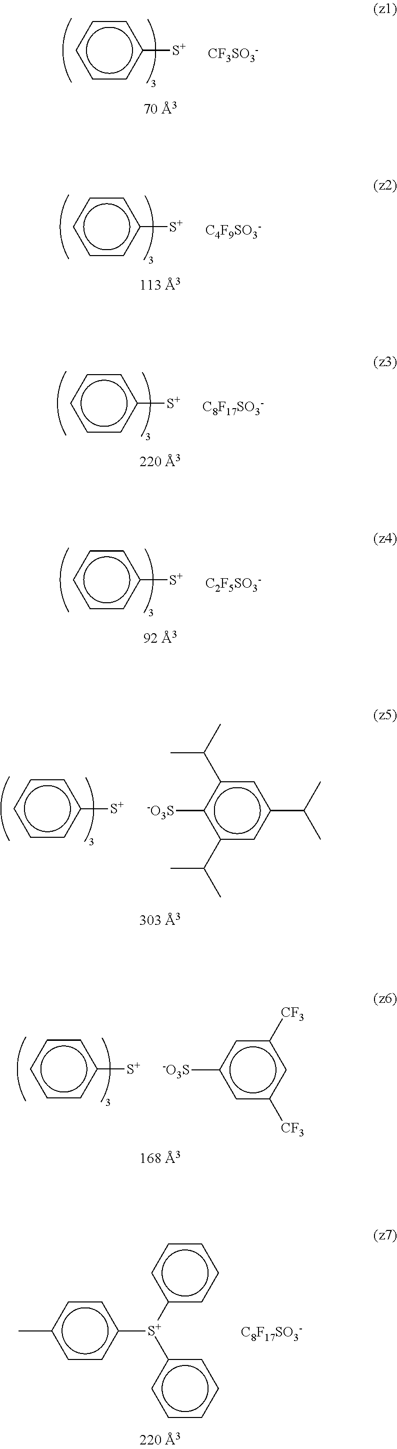

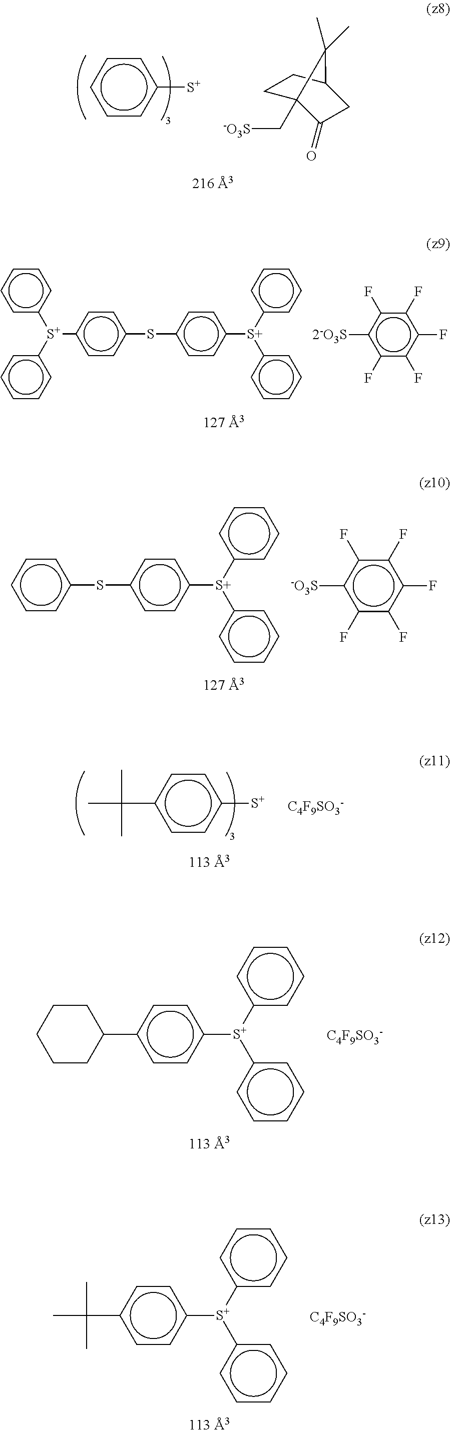

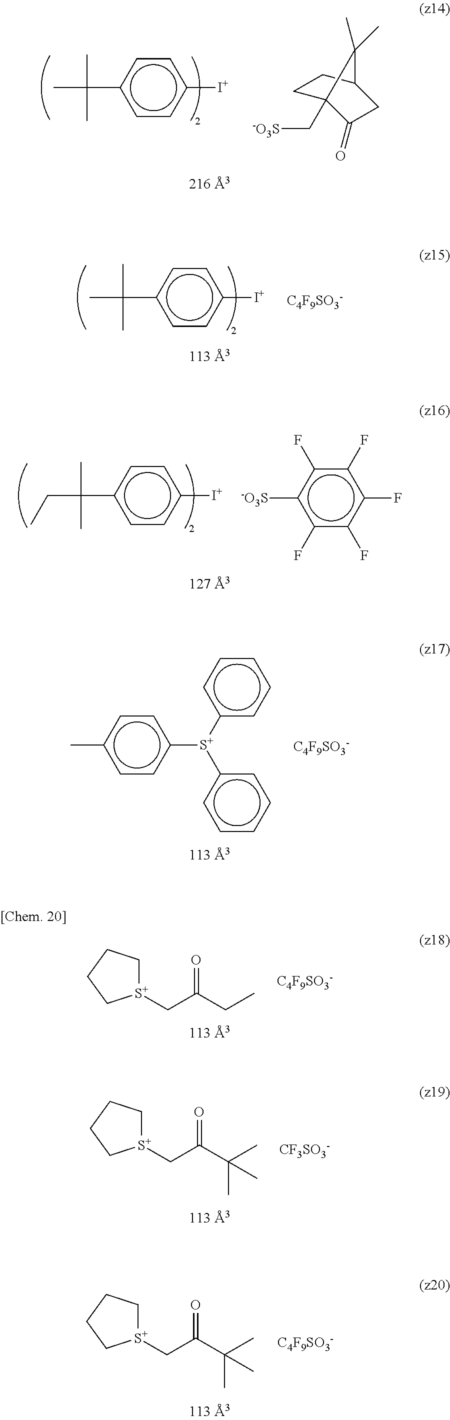

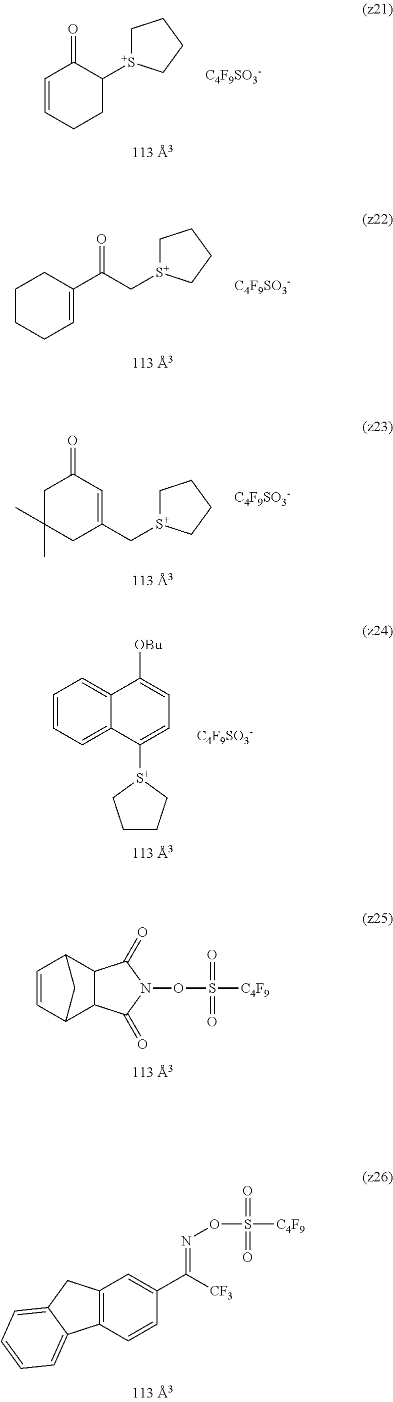

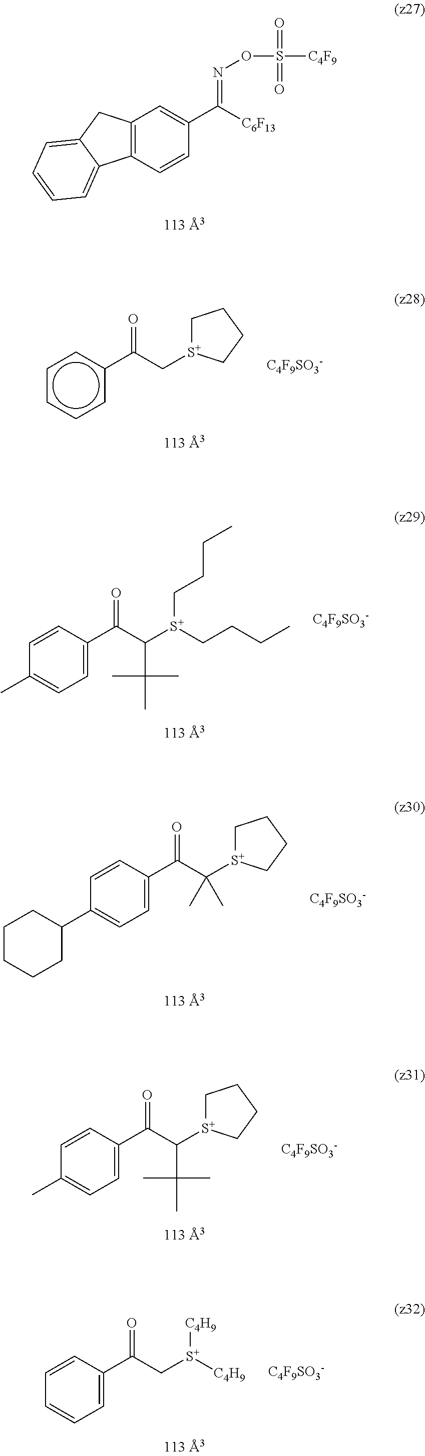

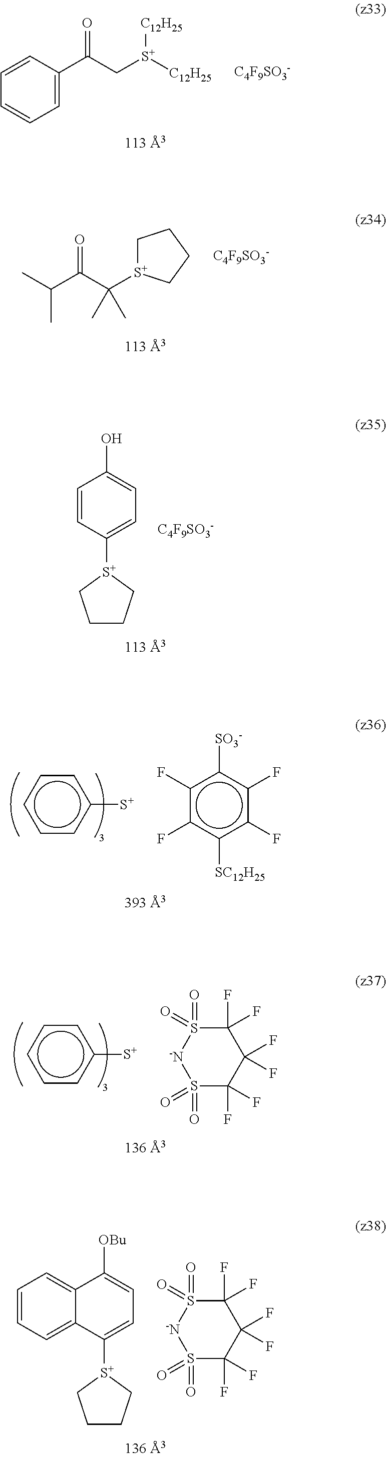

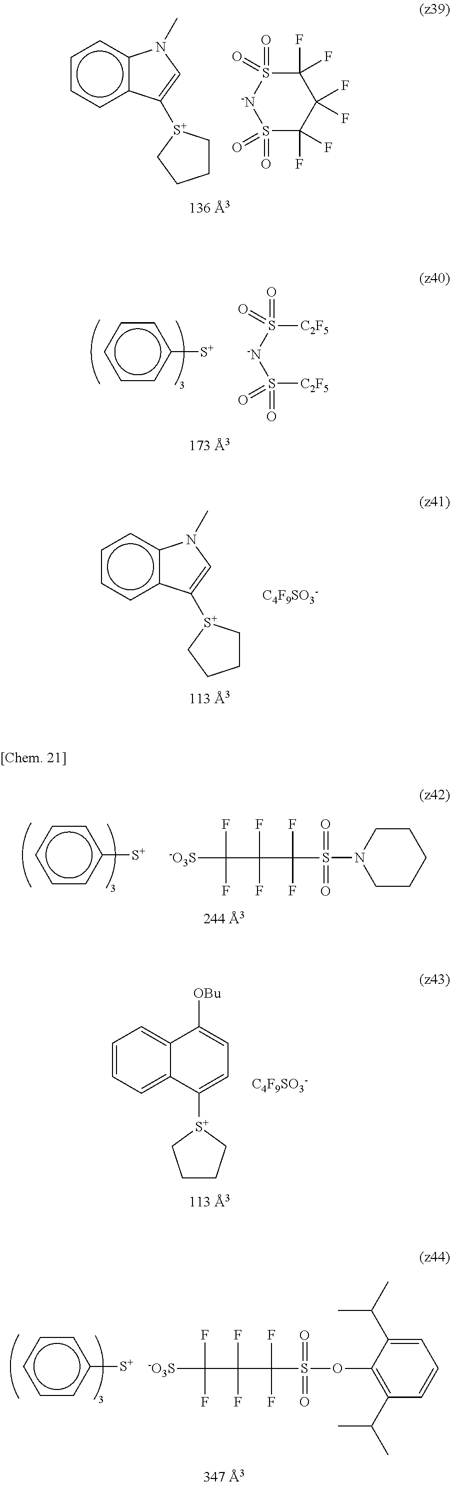

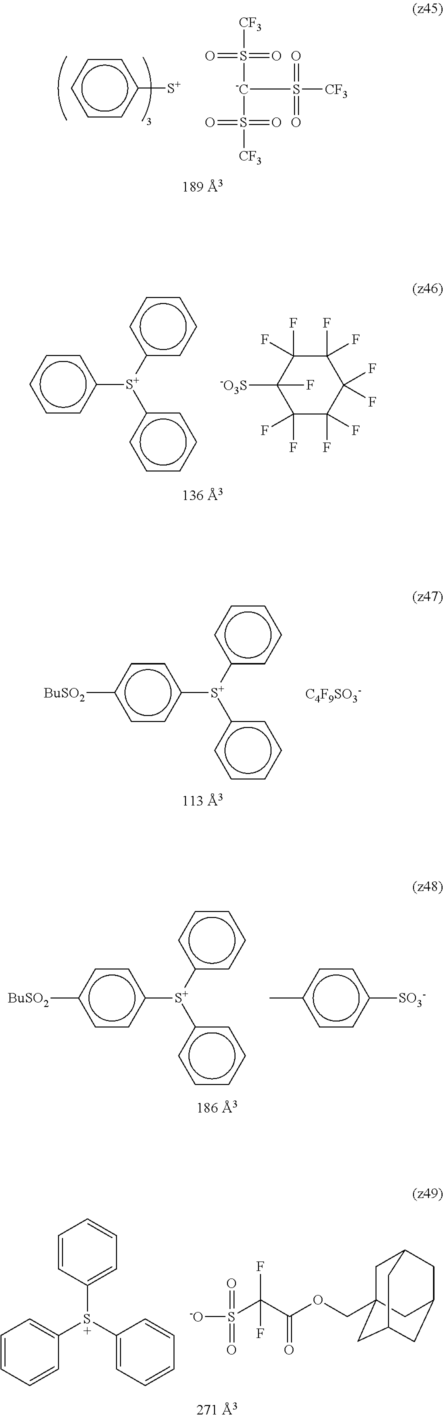

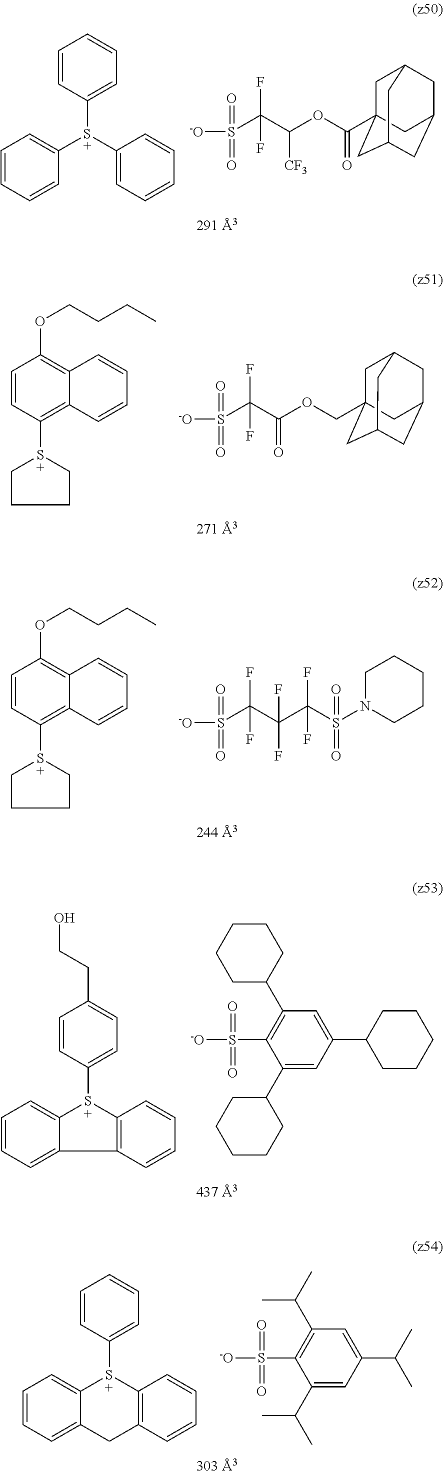

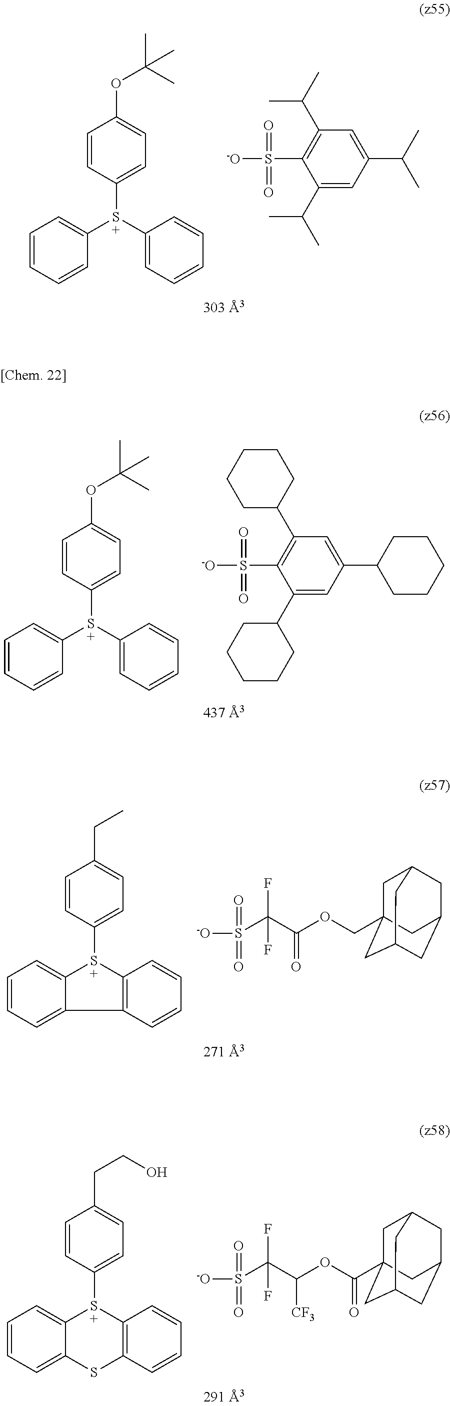

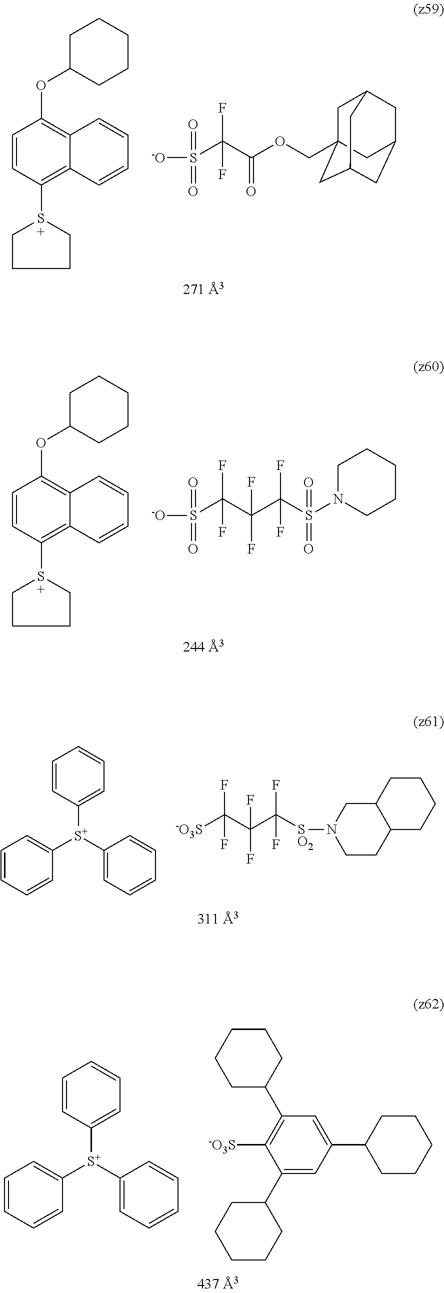

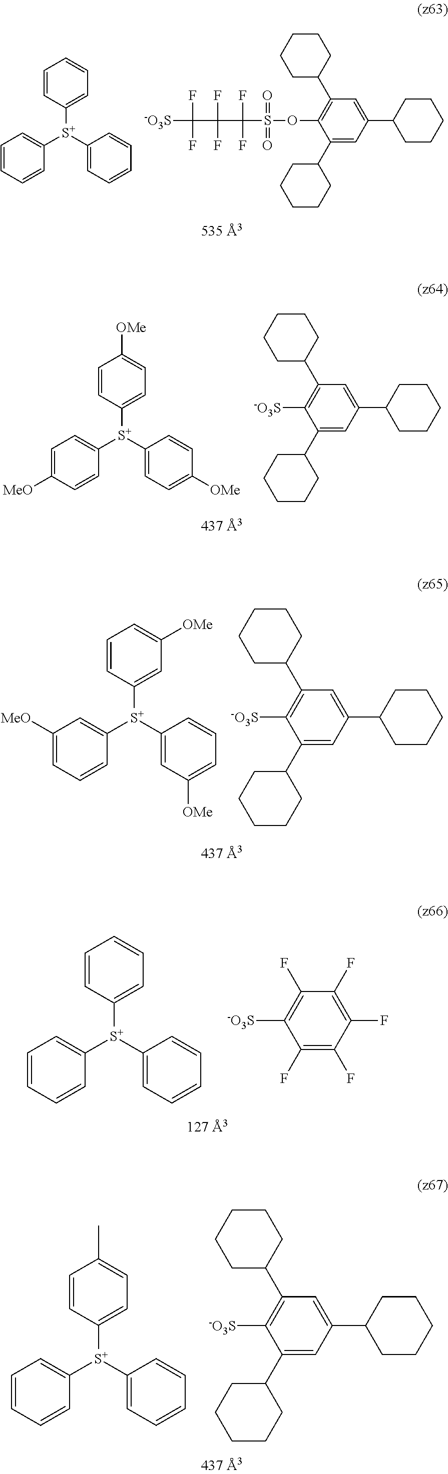

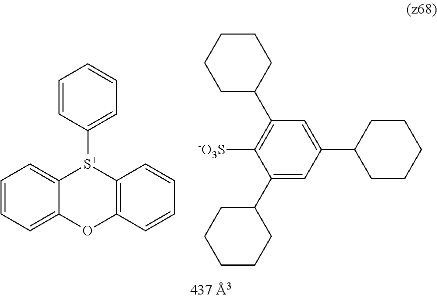

Furthermore, as the acid generator (preferably, an onium compound) used in the present invention, a polymer type acid generator in which a group which generates an acid when irradiated with actinic rays or radiation (photoacid generating group) is introduced into the main chain or a side chain of a polymer compound, can also be used. Such an acid generator is indicated as a repeating unit having a photoacid generating group in the descriptions for the polymer compound (A).

The content of the acid generator (B) in the composition is preferably 0.1 mass % to 40 mass %, more preferably 0.5 mass % to 30 mass %, and even more preferably 1 mass % to 25 mass %, relative to the total solid content of the composition.

One kind of the acid generator (B) can be used alone, or two or more kinds can be used in combination.

[3] (C) Cross-Linking Agent

The negative chemical amplification resist composition of the present invention contains a cross-linking agent (C). The negative chemical amplification resist composition of the present invention preferably contains, as the cross-linking agent (C), a compound which cross-links the polymer compound (A) by the action of an acid (hereinafter, appropriately referred to as an acid cross-linking agent or simply as a cross-linking agent).

The cross-linking agent (C) is preferably a compound having 2 or more hydroxymethyl groups or alkoxymethyl groups in the molecule as cross-linkable groups.

Preferred examples of the cross-linking agent include hydroxymethylated or alkoxymethylated phenol compounds, alkoxymethylated melamine-based compounds, alkoxymethyl glycoluril-based compounds, and alkoxymethylated urea-based compounds. More preferred examples include hydroxymethylated or alkoxymethylated phenol compounds, alkoxymethylated melamine-based compounds, and alkoxymethyl glycoluril-based compounds, and hydroxymethylated or alkoxymethylated phenol compounds are most preferred from the viewpoint of pattern shape.

Particularly preferred examples of the cross-linking agent (C) include a phenol derivative which contains 3 to 5 benzene rings in the molecule, has two or more hydroxymethyl groups or alkoxymethyl groups in total, and has a molecular weight of 1200 or less; and a melamine-formaldehyde derivative or an alkoxymethyl glycoluril derivative, which has at least two free N-alkoxymethyl groups.

The alkoxymethyl group is preferably a methoxymethyl group or an ethoxymethyl group.

Among the cross-linking agents, the phenol derivative having a hydroxymethyl group can be obtained by allowing a corresponding phenol compound which does not have a hydroxymethyl group and formaldehyde to react in the presence of a base catalyst. Furthermore, the phenol derivative having an alkoxymethyl group can be obtained by allowing a corresponding phenol derivative having a hydroxymethyl group and an alcohol to react in the presence of an acid catalyst.

Among the phenol derivatives synthesized as such, a phenol derivative having an alkoxymethyl group is particularly preferred from the viewpoints of sensitivity, storage stability, and pattern shape.

Other preferred examples of the cross-linking agent include compounds having N-hydroxymethyl groups or N-alkoxymethyl groups, such as alkoxymethylated melamine-based compounds, alkoxymethyl glycoluril-based compounds, and alkoxymethylated urea-based compounds.

Examples of these compounds include hexamethoxymethyl melamine, hexaethoxymethyl melamine, tetramethoxymethyl glycoluril, 1,3-bismethoxymethyl-4,5-bismethoxyethylene urea, and bismethoxymethyl urea, and these are disclosed in EP 0,133,216 A, German Patent 3,634,671, German Patent 3,711,264, and EP 0, 232, 482 A.

Particularly preferred examples among these cross-linking agents will be shown below.

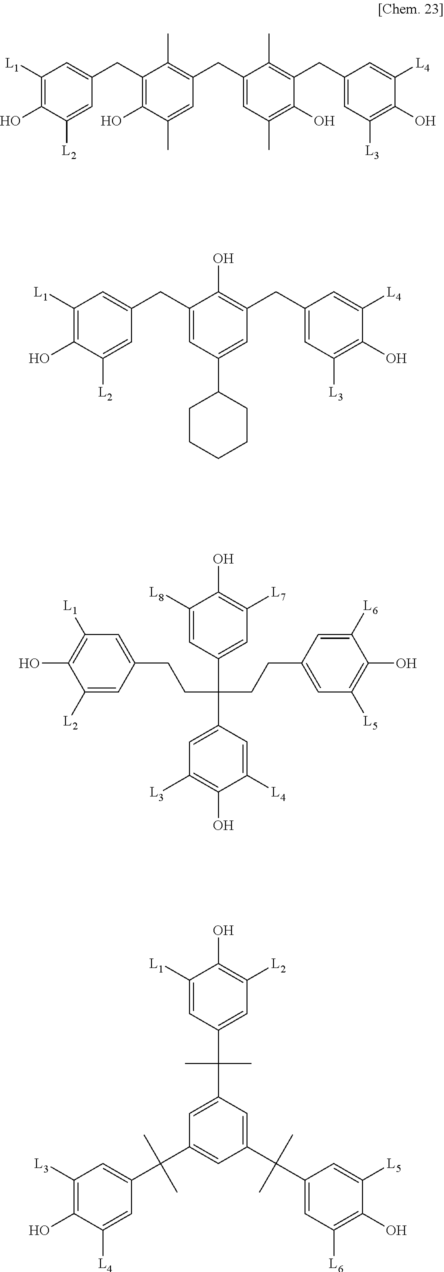

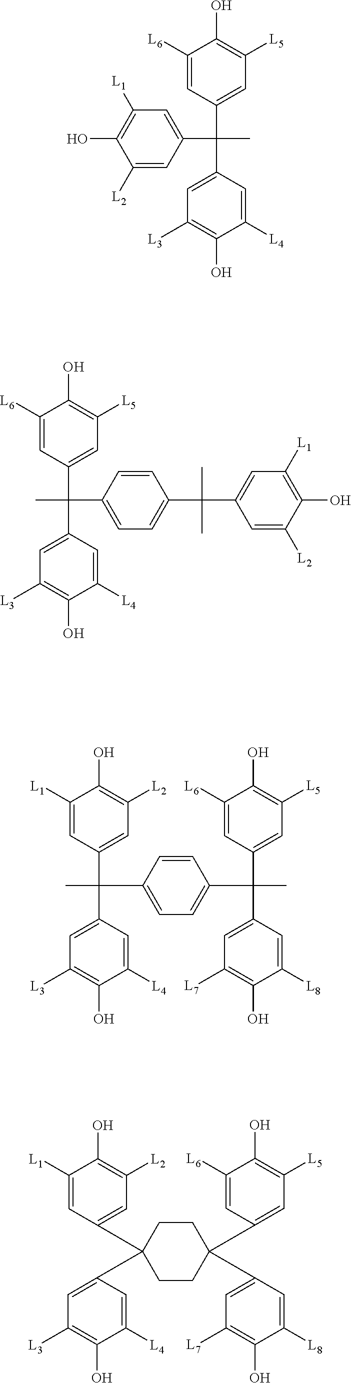

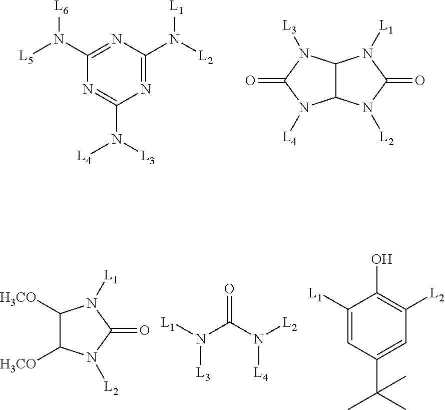

wherein L₁ to L₈ each independently represent a hydrogen atom, a hydroxymethyl group, a methoxymethyl group, an ethoxymethyl group, or an alkyl group having 1 to 6 carbon atoms.

When the negative chemical amplification resist composition according to the present invention contains a cross-linking agent, the cross-linking agent is preferably used in an addition amount of 3 mass % to 40 mass %, and more preferably 5 mass % to 30 mass %, in the solids content of the negative chemical amplification resist composition. When the amount of the cross-linking agent added is set to 3 mass % to 40 mass %, decreases in the residual film ratio and resolution are prevented, and the stability upon storage of the resist liquid can be satisfactorily maintained.

According to the present invention, the cross-linking agent may be used alone, or two or more kinds may be used in combination. From the viewpoint of the pattern shape, it is preferable to use two or more kinds in combination.

For example, when another cross-linking agent, for example, the aforementioned compound having an N-alkoxymethyl group, is used in combination with the phenol derivative described above, the proportion of the phenol derivative and the other cross-linking agent is, as a molar ratio, 100/0 to 20/80, preferably 90/10 to 40/60, and more preferably 80/20 to 50/50.

Furthermore, it is also preferable to use two or more different kinds of phenol derivatives in combination. For example, a combination of two or more kinds of phenol derivatives having a hydroxymethyl group or an alkoxymethyl group can appropriately adjust the dissolution rate of the composition thus obtainable, and can reduce scum. Therefore, it is preferable. Also, a combination of two or more kinds of phenol derivatives, which includes at least a phenol derivative having a tetrafunctional or higher-functional alkoxymethyl group and a phenol derivative having a bifunctional or higher-functional alkoxymethyl group is most preferred because scum can be reduced.

[4] Basic Compound

The negative chemical amplification resist composition of the present invention preferably contains a basic compound as an acid complement agent, in addition to the components described above. When a basic compound is used, the performance change due to the passage of time from the exposure to the post-heating can be reduced. Such a basic compound is preferably an organic basic compound, and more specific examples thereof include aliphatic amines, aromatic amines, heterocyclic amines, nitrogen-containing compounds having carboxyl groups, nitrogen-containing compounds having sulfonyl groups, nitrogen-containing compounds having hydroxyl groups, nitrogen-containing compounds having hydroxyphenyl groups, alcoholic nitrogen-containing compounds, amide derivatives, and imide derivatives. An amine oxide compound (a compound having a methyleneoxy unit and/or an ethyleneoxy unit is preferred, and examples thereof include the compounds described in JP 2008-102383 A), and an ammonium salt (this is preferably a hydroxide or a carboxylate; and more specifically, a tetraalkyl ammonium hydroxide represented by tetrabutyl ammonium hydroxide is preferred from the viewpoint of line edge roughness (LER)) are also appropriately used.

Furthermore, a compound which has increasing basicity under the action of an acid can also be used as one kind of the basic compound.

Specific examples of the amines include tri-n-butylamine, tri-n-pentylamine, tri-n-octylamine, tri-n-decylamine, triisodecylamine, dicyclohexylmethylamine, tetradecylamine, pentadecylamine, hexadecylamine, octadecylamine, didecylamine, methyloctadecylamine, dimethylundecylamine, N,N-dimethyldodecylamine, methyldioctadecylamine, N,N-dibutylaniline, N,N-dihexylaniline, 2,6-diisopropylaniline, 2,4,6-tri(t-butyl)aniline, triethanolamine, N,N-dihydroxyethylaniline, tris(methoxyethoxyethyl)amine; the compounds exemplified in column 3, line 60 of U.S. Pat. No. 6,040,112 B; 2-[2-{2-(2,2-dimethoxyphenoxyethoxy)ethyl}-bis-(2-methoxyethyl)]-amine; and compounds (C1-1) to (C3-3) exemplified in paragraph [0066] of US 2007/0224539 A1. Examples of the compounds having nitrogen-containing heterocyclic structures include 2-phenylbenzoimidazole, 2,4,5-triphenylimidazole, N-hydroxyethylpiperidine, bis(1,2,2,6,6-pentamethyl-4-piperidyl) sebacate, 4-dimethylaminopyridine, antipyrine, hydroxyantipyrine, 1,5-diazabicyclo[4.3.0]-none-5-ene, 1,8-diazabicyclo[5.4.0]-undeca-7-ene, and tetrabutylammonium hydroxide.

Furthermore, a photodegradable basic compound (a compound in which a basic nitrogen atom initially acts as a base and thereby the compound exhibits basicity, but as the compound is degraded by irradiation of actinic rays or radiation and generates a zwitterionic compound having a basic nitrogen atom and an organic acid moiety, these moieties are neutralized in the molecule, and basicity is decreased or lost. For example, the onium salts described in JP 3577743 B, JP 2001-215689 A, JP 2001-166476 A, and JP 2008-102383 A), and a photobase generator (for example, the compounds described in JP 2010-243773 A) are also appropriately used.

Among these basic compounds, an ammonium salt or a photodegradable basic compound is preferred from the viewpoint of LER.

According to the present invention, the basic compound may be used alone, or two or more kinds may be used in combination.

The content of the basic compound used in the present invention is preferably 0.01 mass % to 10 mass %, more preferably 0.03 mass % to 5 mass %, and particularly preferably 0.05 mass % to 3 mass %, relative to the total solids content of the negative chemical amplification resist composition.

[5] Surfactant

The negative chemical amplification resist composition of the present invention may further contain a surfactant in order to enhance coatability. Examples of the surfactant include, but are not particularly limited to, nonionic surfactants such as polyoxyethyelne alkyl ethers, polyoxyethylene alkyl allyl ethers, polyoxyethylene polyoxypropylene block copolymers, sorbitan fatty acid esters, and polyoxyethylene sorbitan fatty acid esters; fluorine-based surfactants such as MEGAFACE F171 (manufactured by Dainippon Ink and Chemicals, Inc.), Fluorad FC430 (manufactured by Sumitomo 3M, Ltd.), Surfinol E1004 (manufactured by Asahi Glass Co., Ltd.), PF656 and PF6320 manufactured by Omnova Solutions, Inc.; and organosiloxane polymers.

When the negative chemical amplification resist composition contains a surfactant, the amount of the surfactant used is preferably 0.0001 mass % to 2 mass %, and more preferably 0.0005 mass % to 1 mass %, relative to the total amount (excluding the solvent) of the composition.

[6] Organic Carboxylic Acid

The negative chemical amplification resist composition of the present invention preferably contains an organic carboxylic acid in addition to the components described above. Examples of such an organic carboxylic acid compound include aliphatic carboxylic acids, alicyclic carboxylic acids, unsaturated aliphatic carboxylic acids, oxycarboxylic acids, alkoxycarboxylic acids, ketocarboxylic acids, benzoic acid derivatives, phthalic acid, terephthalic acid, isophthalic acid, 2-naphthoic acid, 1-hydroxy-2-naphthoic acid, and 2-hydroxy-3-naphthoic acid. However, since there is a risk that when exposure to an electron beam is carried out in a vacuum, the organic carboxylic acid compound may evaporate from the resist film surface and contaminate the drawing chamber, preferred compounds include aromatic organic carboxylic acids, and among them, for example, benzoic acid, 1-hydroxy-2-naphthoic acid, and 2-hydroxy-3-naphthoic acid are suitable.

The mixing amount of the organic carboxylic acid is preferably in the range of 0.01 parts by mass to 10 parts by mass, more preferably 0.01 parts by mass to 5 parts by mass, and even more preferably 0.01 parts by mass to 3 parts by mass, relative to 100 parts by mass of the polymer compound (A).

The negative chemical amplification resist composition of the present invention may further contain a dye, a plasticizer, an acid proliferating agent (described in WO 95/29968, WO 98/24000, JP 1996-305262 A (JP-H08-305262 A), JP 1997-034106 A (JP-H09-034106 A), JP 1996-248561 A (JP-H08-248561 A), JP 1996-503082 A (JP-H08-503082 A), U.S. Pat. No. 5,445,917 B, JP 1996-503081 A (JP-H08-503081 A), U.S. Pat. No. 5,534,393 B, U.S. Pat. No. 5,395,736 B, U.S. Pat. No. 5,741,630 B, U.S. Pat. No. 5,334,489 B, U.S. Pat. No. 5,582,956 B, U.S. Pat. No. 5,578,424 B, U.S. Pat. No. 5,453,345 B, U.S. Pat. No. 5,445,917 B, EP 665,960 B, EP 757,628 B, EP 665,961 B, U.S. Pat. No. 5,667,943 B, JP 1998-001508 A (JP-H10-001508 A), JP 1998-282642 A (JP-H10-282642 A), JP 1997-512498 A (JP-H09-512498), JP 2000-062337 A, JP-2005-017730 A, JP 2008-209889 A, and the like), and the like, if necessary. Examples of these compounds include the respective compounds described in JP 2008-268935 A.

[Carboxylic Acid Onium Salt]

The negative chemical amplification resist composition of the present invention may also contain a carboxylic acid onium salt. Examples of the carboxylic acid onium salt include a carboxylic acid sulfonium salt, a carboxylic acid iodonium salt, and a carboxylic acid ammonium salt. Particularly, the carboxylic acid onium salt is preferably a carboxylic acid iodonium salt or a carboxylic acid sulfonium salt. Furthermore, according to the present invention, it is preferable that the carboxylate residue of the carboxylic acid onium salt not contain an aromatic group or a carbon-carbon double bond. As a particularly preferred anionic moiety, a linear or branched, monocyclic or polycyclic cyclic alkylcarboxylic acid anion having 1 to 30 carbon atoms is preferred. More preferably, an anion of a carboxylic acid in which a part or all of these alkyl groups are fluorine-substituted, is preferred. Also, the carboxylic acid onium salt may contain an oxygen atom in the alkyl chain. Thereby, transparency to light having a wavelength of 220 nm or less is secured, and sensitivity and resolving power are enhanced, while the coarseness or compactness dependency and exposure margin are improved.

The solvent used in the negative chemical amplification resist composition of the present invention is preferably, for example, ethylene glycol monoethyl ether acetate, cyclohexanone, 2-heptanone, propylene glycol monomethyl ether (PGME, also known as 1-methoxy-2-propanol), propylene glycol monomethyl ether acetate (PGMEA, also known as 1-methoxy-2-acetoxypropane), propylene glycol monomethyl ether propionate, propylene glycol monoethyl ether acetate, methyl 3-methoxypropionate, ethyl 3-ethoxypropionate, methyl β-methoxyisobutyrate, ethyl butyrate, propyl butyrate, methyl isobutyl ketone, ethyl acetate, isoamyl acetate, ethyl lactate, toluene, xylene, cyclohexyl acetate, diacetone alcohol, N-methylpyrrolidone, N,N-dimethylformamide, γ-butyrolactone, N,N-dimethylacetamide, propylene carbonate, or ethylene carbonate. These solvents may be used individually or in combination.

The solid components of the negative chemical amplification resist composition dissolves in the aforementioned solvents, and it is preferable that the solid components be dissolved at a solids concentration of 1 mass % to 30 mass %, more preferably 1 mass % to 20 mass %, and even more preferably 3 mass % to 15 mass %.

The present invention also relates to a resist film formed by the negative chemical amplification resist composition of the present invention, and such a resist film is formed when, for example, the negative chemical amplification resist composition is applied on a support such as a substrate. The thickness of this resist film is preferably 10 nm to 150 nm, and more preferably 10 nm to 120 nm. Regarding the method of applying the resist composition on a substrate, the resist composition is applied on a substrate by an appropriate coating method such as spin coating, roll coating, flow coating, dip coating, spray coating, or doctor coating, but spin coating is preferred, and the speed of rotation is preferably 1000 rpm to 3000 rpm. The coating film is prebaked for 1 minute to 20 minutes at 60° C. to 150° C., and preferably for 1 minute to 10 minutes at 80° C. to 120° C., to form a thin film.

As the material that constitutes the substrate to be processed and its outermost layer, for example, in the case of a semiconductor wafer, a silicon wafer can be used. Examples of the material that forms the outermost layer include Si, SiO₂, SiN, SiON, TiN, WSi, BPSG, and SOG organic antireflection films.

Furthermore, the present invention also relates to resist-coated mask blanks, which have the resist film obtainable as described above. In the case of forming a resist pattern on photomask blanks for photomask production in order to obtain such resist-coated mask blanks, examples of a transparent substrate to be used include transparent substrates of quartz and calcium fluoride. Generally, a light-shielding film, an antireflection film, and a phase shift film, with any necessary one of additional functional films such as an etching stopper film and an etching mask film are laminated on the substrate. As the material of the functional films, films containing silicon or a transition metal such as chromium, molybdenum, zirconium, tantalum, tungsten, titanium, or niobium are laminated. Furthermore, examples of the material to be used in the outermost layer include a material which has, as a main constituent material, a material containing silicon or silicon with oxygen and/or nitrogen; and a silicon compound material which has, as a main constituent material, a material containing transition metals in addition thereto; and a transition metal compound material which has, as a main constituent material, transition metals, in particular, at least one selected from chromium, molybdenum, zirconium, tantalum, tungsten, titanium and niobium, or a material further containing at least one element selected from oxygen, nitrogen and carbon in addition thereto.

The light-shielding film may be a single layer, but a multilayer structure including the laminated plural materials is more preferable. In a case of the multilayer structure, the film thickness per layer is not particularly limited, but the thickness is preferably 5 nm to 100 nm, and more preferably 10 nm to 80 nm. The thickness of the entire light-shielding film is not particularly limited, but the thickness is preferably 5 nm to 200 nm, and more preferably 10 nm to 150 nm.

Among these materials, generally, when pattern formation is carried out on photomask blanks which have a material containing oxygen or nitrogen together with chromium in the outermost layer, by using the negative chemical amplification resist composition, a so-called undercut shape by which a constricted shape is formed near the substrate is likely to be produced. However, in the case of using the composition of the present invention, the problem of undercut can be improved as compared with those of the related art.

Subsequently, the actinic rays or radiation (an electron beam, or the like) are irradiated to this resist film, preferably baking (usually 80° C. to 150° C., and more preferably 90° C. to 130° C., usually 1 minute to 20 minutes, and preferably 1 minute to 10 minutes) is carried out, and thereafter the resist film is developed. Thereby, a satisfactory pattern can be obtained. Thus, a semiconductor fine circuit and a mold structure for imprint, a photomask or the like are produced by using this pattern as a mask, and conducting an appropriate etching treatment, ion implantation and the like.

Meanwhile, the process in the case of producing the mold for imprint by using the composition of the present invention is disclosed in, for example, JP 4109085B, JP 2008-162101 A, and “Fundamentals and Technological Development and Application Deployment of Nanoimprint—Nanoimprint Substrate Technology and Recent Technology Deployment, edited by Hirai, Yoshihiko, published by Frontier Publishing Co., Ltd.”

The usage form of the negative chemical amplification resist composition and the method for forming a resist pattern according to the present invention will be described below.

The present invention also relates to a method for forming a resist pattern, which includes exposing the resist film or the resist-coated mask blanks, and developing the exposed resist film or the exposed resist-coated mask blanks. In the present invention, it is preferable that the exposure be performed by using an electron beam or extreme ultraviolet rays.

In the production of precision integrated circuit elements and the like, first, it is preferable to conduct the exposure onto the resist film (a pattern forming process) by irradiating patternwise the resist film of the present invention with an electron beam or extreme ultraviolet rays (EUV). The exposure amount is, in the case of an electron beam, about 0.1 μC/cm² to 20 μC/cm², and preferably about 3 μC/cm² to 15 μC/cm², and in the case of an extreme ultraviolet rays, about 0.1 mJ/cm² to 20 mJ/cm², preferably about 3 mJ/cm² to 15 mJ/cm². Subsequently, a resist pattern is formed by performing heating after exposure (post-exposure baking) on a hot plate at 60° C. to 150° C. for 1 minute to 20 minutes, and preferably at 80° C. to 120° C. for 1 minute to 10 minutes, and developing, rinsing and drying the resist pattern. The developer liquid is a 0.1 mass % to 5 mass %, and more preferably 2 mass % to 3 mass % alkaline aqueous solution of tetramethylammonium hydroxide (TMAH), tetrabutylammonium hydroxide (TBAH) or the like, and development is carried out by a routine method such as a dipping method, a puddle method or a spray method, for preferably 0.1 minutes to 3 minutes, and more preferably 0.5 minutes to 2 minutes. The alkali developer may also contain an appropriate amount of an alcohol and/or a surfactant. The pH of the alkali developer is usually 10.0 to 15.0. Particularly, a 2.38 mass % aqueous solution of tetramethylammonium hydroxide is preferred.

The developer liquid may contain an appropriate amount of an alcohol and/or a surfactant as necessary.

The surfactant is not particularly limited, but for example, ionic or nonionic fluorine-based and/or silicone-based surfactants can be used. Examples of such fluorine and/or silicone-based surfactants include the surfactants described in, for example, JP 1987-036663 A (JP-562-36663 A), JP 1986-226746 A (JP-561-226746 A), JP 1986-226745 A (JP-561-226745 A), JP 1987-170950 A (JP-S62-170950 A), JP 1988-034540 A (JP-563-034540 A), JP 1995-230165 A (JP-H07-230165 A), JP 1996-062834 A (JP-H08-062834 A), JP 1997-054432 A (JP-H09-054432 A), JP 1997-005988 A (JP-H09-005988 A), U.S. Pat. No. 5,405,720 B, U.S. Pat. No. 5,360,692 B, U.S. Pat. No. 5,529,881 B, U.S. Pat. No. 5,296,330 B, U.S. Pat. No. 5,436,098 B, U.S. Pat. No. 5,576,143 B, U.S. Pat. No. 5,294,511 B, and U.S. Pat. No. 5,824,451 B, and preferably nonionic surfactants are used. The nonionic surfactants are not particularly limited, but it is more preferable to use a fluorine-based surfactant or a silicone-based surfactant.

The amount of the surfactant used is usually 0.001 mass % to 5 mass %, preferably 0.005 mass % to 2 mass %, and more preferably 0.01 mass % to 0.5 mass %, relative to the total amount of the developer liquid.

Regarding the developing method, for example, a method of immersing the substrate in a bath filled with a developer liquid for a certain time (dipping method); a method of performing development by raising the developer liquid on the substrate surface by means of surface tension, and making the developer liquid suspended for a certain time (puddle method); a method of spraying the developer liquid on the substrate surface (spray method); and a method of continuously ejecting the developer liquid while scanning the developer liquid ejection nozzle at a constant rate on the substrate which is rotating at a constant rate (dynamic dispensing method); and the like can be applied.

When the various developing methods include a process of ejecting a developer liquid from the developing nozzle of a developing apparatus toward a resist film, the ejection pressure of the developer liquid that is ejected (flow rate per unit area of the developer liquid that is ejected) is preferably 2 mL/sec/mm² or less, more preferably 1.5 mL/sec/mm² or less, and even more preferably 1 mL/sec/mm² or less. The lower limit of the flow rate is not particularly limited, but in consideration of the throughput, the flow rate is preferably 0.2 mL/sec/mm² or greater.

When the ejection pressure of the developer liquid that is ejected is adjusted to the range described above, the defects of the pattern originating from resist scum after the development can be significantly reduced.

The details of this mechanism is not clearly known, but it is speculated that when the ejection pressure is adjusted to the range described above, the pressure exerted by the developer liquid to the resist film is decreased, and the resist film and the resist pattern are prevented from being carelessly cut out or destroyed.

The ejection pressure (mL/sec/mm²) of the developer liquid is the value at the developing nozzle outlet in the developing apparatus.

Examples of the method of adjusting the ejection pressure of the developer liquid include a method of adjusting the ejection pressure with a pump or the like, and a method of changing the pressure by adjusting the pressure through the supply from a pressurized tank.

Furthermore, a process of suspending development while exchanging the solvent may be carried out after the process of developing by using a developer liquid.

As the rinsing liquid for the rinsing treatment carried out after alkali development, pure water is used, and an appropriate amount of a surfactant can also be added to the water used.

As such, in the resist film formed from the negative chemical amplification resist composition of the present invention, the resist film in the unexposed areas is dissolved, while in the exposed areas, since the polymer compound is crosslinked, the exposed areas are not easily dissolved in the developer liquid. Thus, a desired pattern is formed on the substrate.

Furthermore, the present invention also relates to a photomask obtainable by exposing and developing the resist-coated mask blanks. Regarding the exposure and development, the processes described above are applied. The photomask is suitably used for the manufacture of semiconductors.

The photomask according to the present invention may be a light-transmissive mask used for ArF excimer lasers and the like, or may be a light-reflective mask used in reflection lithography using EUV light as the light source.

Furthermore, the present invention also relates to a method for producing a semiconductor device, including the resist pattern forming method of the present invention described above, and a semiconductor device produced by this production method.

The semiconductor device of the present invention is suitably mounted in electric and electronic instruments (electrical appliances, OA and media-related equipment, optical instruments, and communication devices).

### EXAMPLES

Hereinafter, embodiments of the present invention will be more specifically described based on Examples. However, the present invention is not intended to be limited to these Examples. In the following Synthesis Examples and Examples, the structures of the compounds were confirmed by an ¹H-NMR analysis.

(I) Examples of Negative Chemical Amplification Resist (Electron Beam and Alkali Development)

### 1. Synthesis Example of Polymer Compound (A) (Component (A))

### Synthesis Example 1

### Synthesis of Polymer Compound (A1)

A mixed solution of 25.95 parts by mass of 4-acetoxystyrene, 8.81 parts by mass of a monomer (M−1) described below, 83.4 parts by mass of 1-methoxy-2-propanol, and 2.30 parts by mass of dimethyl 2,2′-azobis(2-methylpropionate) [V-601; manufactured by Wako Pure Chemical Industries, Ltd.] was prepared.

20.9 parts by mass of 1-methoxy-2-propanol was heated to 80° C. under a nitrogen gas stream. Thereafter, while this liquid was stirred, the mixed solution was added dropwise thereto over 2 hours. After completion of the dropwise addition, the mixture was further stirred for 2 hours at 80° C. Next, the mixture was heated to 85° C. and further stirred for 2 hours.

The reaction liquid was left to cool, and then 0.60 g of a 28 wt % methanol solution of sodium methoxide was added thereto to allow to react for 2 hours. Subsequently, the reaction mixture was neutralized with a 1 N aqueous HCl solution, distilled water was added thereto, and then the organic layer was extracted with ethyl acetate. The extract liquid was allowed to reprecipitate by using a large amount of hexane/ethyl acetate. Thereafter, the obtained precipitate was subjected to drying in a vacuum, and thus 27.0 parts by mass of a polymer compound (A1) was obtained.

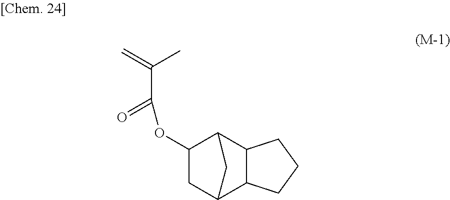 [SMILES: C=C(C)C(=O)OC1CC2CC1C1CCCC21]

Furthermore, other polymer compounds were synthesized in the same manner as in the case of the polymer compound (A1).

For the polymer compounds thus obtained, the composition ratios (molar ratio) of the polymer compounds were calculated by a ¹H-NMR analysis. Furthermore, the weight average molecular weight (Mw, calculated relative to polystyrene standards), the number average molecular weight (Mn, calculated relative to polystyrene standards), and dispersity (Mw/Mn) was calculated by a gel permeation chromatography (GPC) (solvent: THF) analysis. The weight average molecular weight and dispersity are shown in the following tables together with the chemical formulae and composition ratios of the polymer compounds.

Furthermore, as polymer compounds for comparison, comparative polymer compounds (A1) to (A3) having the structures, composition ratios, weight average molecular weight (Mw) and dispersity (Mw/Mn) as indicated in Table 1 were prepared.

TABLE 1

| | | | Weight | |
|---|---|---|---|---|
| | | Composition | average | |
| Polymer | | ratio | molecular | |
| compound | Chemical formula | (molar ratio) | weight | Dispersity |
| Polymer compound (A1) | 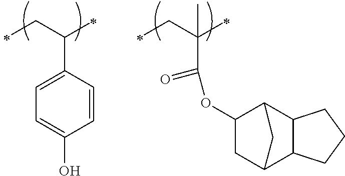 | 80/20 | 7500 | 1.31 |
| Polymer compound (A2) | 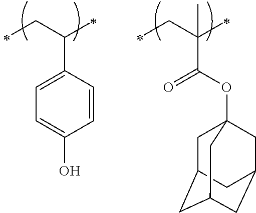 | 85/15 | 6600 | 1.32 |
| Polymer compound (A3) | 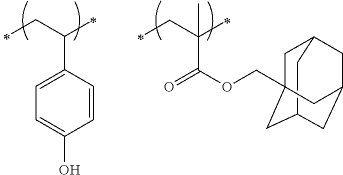 | 85/15 | 5500 | 1.25 |
| Polymer compound (A4) | 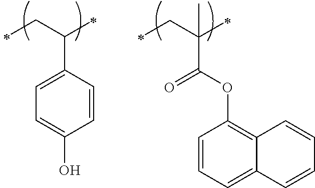 | 90/10 | 4400 | 1.44 |
| Polymer compound (A5) | 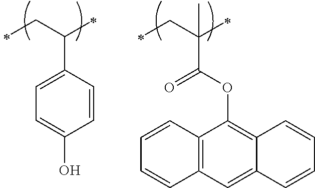 | 90/10 | 6500 | 1.45 |
| Polymer compound (A6) | 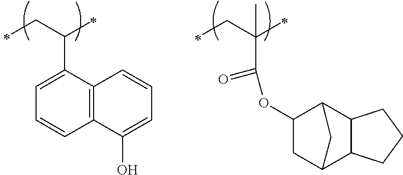 | 85/15 | 9500 | 1.31 |
| Polymer compound (A7) | 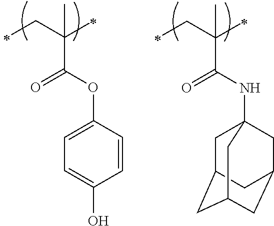 | 80/20 | 3400 | 1.22 |
| Polymer compound (A8) | 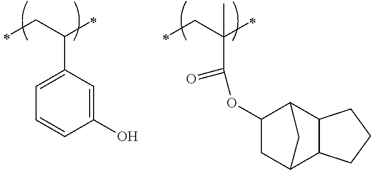 | 90/10 | 4500 | 1.31 |
| Polymer compound (A9) | 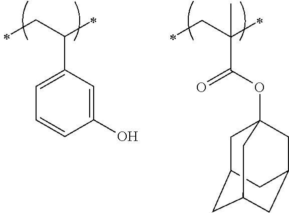 | 90/10 | 5500 | 1.23 |
| Polymer compound (A10) | 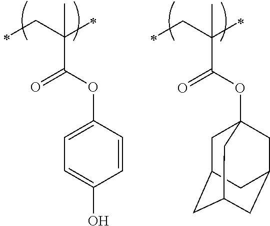 | 85/15 | 6200 | 1.30 |
| Polymer compound (A11) | 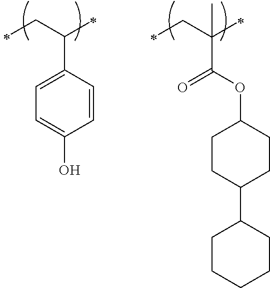 | 70/30 | 5500 | 1.30 |
| Comparative polymer compound (A1) | 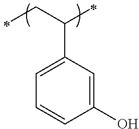 | 100 | 4500 | 1.13 |
| Comparative polymer compound (A2) | 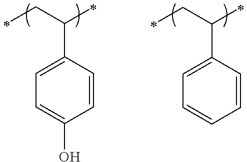 | 90/10 | 8000 | 1.51 |
| Comparative polymer compound (A3) | 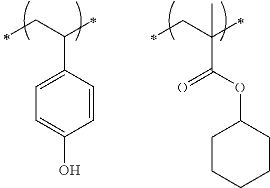 | 85/15 | 6200 | 1.30 |

### 2. Examples

### Example 1E

(1) Preparation of Support

On a 6-inch wafer (a wafer subjected to a shielding film treatment used for conventional photomask blanks), chromium (Cr) oxide was deposited, and thus a support was prepared.

(2) Preparation of Resist Coating Solution

(Coating solution composition of negative resist composition N1)

| | |
|---|---|
| Polymer compound (A1) | 0.72 g |
| Photoacid generator (z61) (structural formula is described below) | 0.12 g |
| Cross-linking agent CL-1 (structural formula is described below) | 0.08 g |
| Cross-linking agent CL-4 (structural formula is described below) | 0.04 g |
| Tetrabutylammonium hydroxide (basic compound) | 0.002 g |
| 2-Hydroxy-3-naphthoic acid (organic carboxylic acid) | 0.012 g |
| Surfactant PF6320 (manufactured by Omnova Solutions, Inc.) | 0.001 g |
| Propylene glycol monomethyl ether acetate (solvent) | 4.0 g |
| Propylene glycol monomethyl ether (solvent) | 5.0 g |

[Chem. 25]

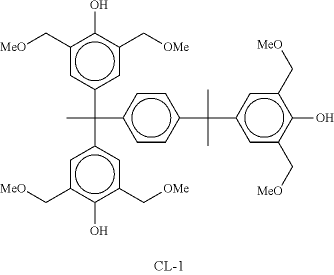

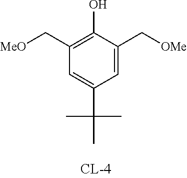 [SMILES: COCc1cc(C(C)(C)C)cc(COC)c1O]

A solution of the composition described above was precision filtered through a polytetrafluoroethylene filter having a pore size of 0.04 μm, and thus a resist coating solution was obtained.

(3) Production of Resist Film

The resist coating solution was applied on the 6-inch wafer by using a spin coater Mark 8 manufactured by Tokyo Electron, Ltd., and the wafer was dried on a hot plate at 110° C. for 90 seconds. Thus, a resist film having a thickness of 100 nm was obtained. That is, a resist-coated mask blanks was obtained.

(4) Production of Negative Resist Pattern

This resist film was subjected to patternwise irradiation by using an electron beam lithographic apparatus (manufactured by Elionix, Inc.; ELS-7500, acceleration voltage: 50 keV). After the irradiation, the system was heated on a hot plate at 120° C. for 90 seconds, and the system was immersed in a 2.38 mass % aqueous solution of tetramethylammonium hydroxide (TMAH) for 60 seconds. Subsequently, the system was rinsed with water for 30 seconds and dried.

(5) Evaluation of Resist Pattern

The pattern thus obtained was evaluated for sensitivity, resolution, scum, pattern shape, line edge roughness (LER), and dry etching resistance, by the methods described below.

[Sensitivity]

The cross-sectional shape of the pattern thus obtained was observed by using a scanning electron microscope (S-4300 manufactured by Hitachi, Ltd.). The amount of exposure (amount of electron beam irradiation) used to resolve a resist pattern having a line width of 100 nm (line:space=1:1) was designated as sensitivity. A smaller value of this amount of exposure means higher sensitivity.

[Resolving Power]

The limit resolving power (minimum line width at which lines and spaces (line space=1:1) are separated and resolved) at the amount of exposure (amount of electron beam irradiation) exhibiting the sensitivity described above was designated as the resolving power (nm).

[Pattern Shape]

The cross-sectional shape of a line pattern (L/S=1/1) having a line width of 100 nm at the amount (amount of electron beam irradiation) of exposure exhibiting the sensitivity described above, was observed by using a scanning electron microscope (S-4300 manufactured by Hitachi, Ltd.). In regard to the cross-sectional shape of the line pattern, a sample in which the ratio represented by [line width at the top (surface area) of the line pattern/line width in the middle of the line pattern (height position at a half of the line pattern height)] is 1.5 or more was designated as “inverse taper”; a sample in which the ratio is greater than or equal to 1.2 and less than 1.5 was designated as “slightly inverse taper”; and a sample in which the ratio is less than 1.2 was designated as “rectangular.” Thus, an evaluation was performed.

[Scum Evaluation]

A line pattern was formed by the same method as described in section [Pattern shape]. Thereafter, a cross-section SEM was obtained by using a scanning electron microscope S4800 (manufactured by Hitachi High Technologies Corp.), and the presence of scum in the space area was observed and evaluated as follows.

C: Scum is observed, and patterns are partially connected to each other.

B: Scum is observed, but patterns are not connected to each other.

A: No scum is observed.

[Line Edge Roughness (Ler)]

A line pattern (L/S=1/1) having a line width of 100 nm was formed with the amount of irradiation (amount of electron beam irradiation) exhibiting the sensitivity described above. At any arbitrary 30 points included in 50 μm along the length direction, the distance from a reference line at which an edge should exist was measured by using a scanning electron microscope (S-9220 manufactured by Hitachi, Ltd.). The standard deviation of this distance was determined, and 3σ was calculated. A smaller value indicates satisfactory performance.

[Dry Etching Resistance]

A resist film on which a resist pattern having a line width of 100 nm (line:space=1:1) was formed at the amount of irradiation (amount of electron beam irradiation) exhibiting the sensitivity described above, was subjected to dry etching for 30 seconds with Ar/C₄F₆/O₂ gas (gas mixture at a volume ratio of 100/4/2) by using HITACHI U-621. Thereafter, the resist residual film ratio was measured and was used as an indicator for dry etching resistance.

Very satisfactory: a residual film ratio of 95% or greater

Satisfactory: a residual film ratio of greater than or equal to 90% and less than 95%

Poor: a residual film ratio of less than 90%

### [Example 2E] to [Example 24E], [Comparative Example 1E] to [Comparative Example 3E]

Preparation of resist coating solutions (negative resist compositions N2 to N24, negative resist comparative compositions N1 to N3), negative pattern formation, and evaluations thereof were carried out in the same manner as in Example 1E, except that the components used in Example 1E were changed to the components described in the following Table 2.

TABLE 2

| | Polymer | | | Cross-linking | |
|---|---|---|---|---|---|
| Composition | compound | Acid generator | Basic compound | agent | Solvent |
| N1 | A1 | z61 | B1 | CL-1/CL-4 | S2/S1 |
| | (0.72 g) | (0.12 g) | (0.002 g) | (0.08 g/0.04 g) | (5.0 g/4.0 g) |
| N2 | A2 | z61 | B1 | CL-1/CL-4 | S1/S3 |
| | (0.72 g) | (0.12 g) | (0.002 g) | (0.08 g/0.04 g) | (5.0 g/4.0 g) |
| N3 | A3 | z61 | B1 | CL-1/CL-4 | S2/S3 |
| | (0.72 g) | (0.12 g) | (0.002 g) | (0.08 g/0.04 g) | (5.0 g/4.0 g) |
| N4 | A4 | z61 | B1 | CL-1/CL-4 | S2/S7 |
| | (0.72 g) | (0.12 g) | (0.002 g) | (0.08 g/0.04 g) | (5.0 g/4.0 g) |
| N5 | A5 | z61 | B1 | CL-1/CL-4 | S2/S1 |
| | (0.72 g) | (0.12 g) | (0.002 g) | (0.08 g/0.04 g) | (5.0 g/4.0 g) |
| N6 | A6 | z61 | B1 | CL-1/CL-4 | S2/S1 |
| | (0.72 g) | (0.12 g) | (0.002 g) | (0.08 g/0.04 g) | (5.0 g/4.0 g) |
| N7 | A7 | z61 | B1 | CL-1/CL-4 | S1/S2/S6 |
| | (0.72 g) | (0.12 g) | (0.002 g) | (0.08 g/0.04 g) | (4.0 g/4.0 g/1.0 g) |
| N8 | A8 | z61 | B1 | CL-1/CL-4 | S1/S2/S5 |
| | (0.72 g) | (0.12 g) | (0.002 g) | (0.08 g/0.04 g) | (4.0 g/4.0 g/1.0 g) |
| N9 | A9 | z61 | B1 | CL-1/CL-4 | S1/S2/S4 |
| | (0.72 g) | (0.12 g) | (0.002 g) | (0.08 g/0.04 g) | (4.0 g/4.0 g/1.0 g) |
| N10 | A10 | z61 | B1 | CL-1/CL-4 | S2/S1 |
| | (0.72 g) | (0.12 g) | (0.002 g) | (0.08 g/0.04 g) | (5.0 g/4.0 g) |
| N11 | A1 | z67 | B1 | CL-1/CL-4 | S2/S1 |
| | (0.72 g) | (0.12 g) | (0.002 g) | (0.08 g/0.04 g) | (5.0 g/4.0 g) |
| N12 | A1/A2 | z68 | B1 | CL-1/CL-4 | S2/S1 |
| | (0.42 g/0.3 g) | (0.12 g) | (0.002 g) | (0.08 g/0.04 g) | (5.0 g/4.0 g) |
| N13 | A1 | z66 | B1/B6 | CL-1/CL-4 | S2/S1 |
| | (0.72 g) | (0.12 g) | (0.001 g/0.001 g) | (0.08 g/0.04 g) | (5.0 g/4.0 g) |
| N14 | A2 | z37 | B1 | CL-1/CL-4 | S2/S1 |
| | (0.72 g) | (0.12 g) | (0.002 g) | (0.08 g/0.04 g) | (5.0 g/4.0 g) |
| N15 | A2 | z5 | B4 | CL-1/CL-4 | S2/S1 |
| | (0.72 g) | (0.12 g) | (0.002 g) | (0.08 g/0.04 g) | (5.0 g/4.0 g) |
| N16 | A1 | z2 | B3 | CL-2/CL-3 | S2/S1 |
| | (0.72 g) | (0.12 g) | (0.002 g) | (0.08 g/0.04 g) | (5.0 g/4.0 g) |
| N17 | A1 | z49 | B2 | CL-1 | S2/S1 |
| | (0.72 g) | (0.12 g) | (0.002 g) | (0.12 g) | (5.0 g/4.0 g) |
| N18 | A2 | z5/z48 | B1/B6 | CL-3 | S2/S1 |
| | (0.72 g) | (0.06 g/0.06 g) | (0.001 g/0.001 g) | (0.12 g) | (5.0 g/4.0 g) |
| N19 | A2 | z37 | B5 | CL-1/CL-4 | S2/S1 |
| | (0.72 g) | (0.12 g) | (0.002 g) | (0.04 g/0.08 g) | (5.0 g/4.0 g) |
| N20 | A2 | z8 | B1 | CL-1/CL-4 | S2/S1 |
| | (0.72 g) | (0.12 g) | (0.002 g) | (0.06 g/0.06 g) | (5.0 g/4.0 g) |
| N21 | A2 | z65 | B1 | CL-1/CL-4 | S2/S1 |
| | (0.72 g) | (0.12 g) | (0.002 g) | (0.08 g/0.04 g) | (5.0 g/4.0 g) |
| N22 | A2 | z63 | B1 | CL-1/CL-4 | S2/S1 |
| | (0.72 g) | (0.12 g) | (0.002 g) | (0.08 g/0.04 g) | (5.0 g/4.0 g) |
| N23 | A2 | z42 | B1 | CL-1/CL-4 | S2/S1 |
| | (0.72 g) | (0.12 g) | (0.002 g) | (0.08 g/0.04 g) | (5.0 g/4.0 g) |
| N24 | A11 | z61 | B1 | CL-1/CL-4 | S2/S1 |
| | (0.72 g) | (0.12 g) | (0.002 g) | (0.08 g/0.04 g) | (5.0 g/4.0 g) |
| Comparative | Comparative | z48 | B2 | CL-3 | S2/S1 |
| composition | polymer | (0.12 g) | (0.002 g) | (0.12 g) | (5.0 g/4.0 g) |
| N1 | compound A1 | | | | |
| | (0.72 g) | | | | |
| Comparative | Comparative | z48 | B2 | CL-3 | S2/S1 |
| composition | polymer | (0.12 g) | (0.002 g) | (0.12 g) | (5.0 g/4.0 g) |
| N2 | compound A2 | | | | |
| | (0.72 g) | | | | |
| Comparative | Comparative | z48 | B2 | CL-3 | S2/S1 |
| composition | polymer | (0.12 g) | (0.002 g) | (0.12 g) | (5.0 g/4.0 g) |
| N3 | compound A3 | | | | |
| | (0.72 g) | | | | |

Abbreviations of the components other than those described above, which were used in the above and following Examples/Comparative Examples, are described below.

[Acid Generator (B)]

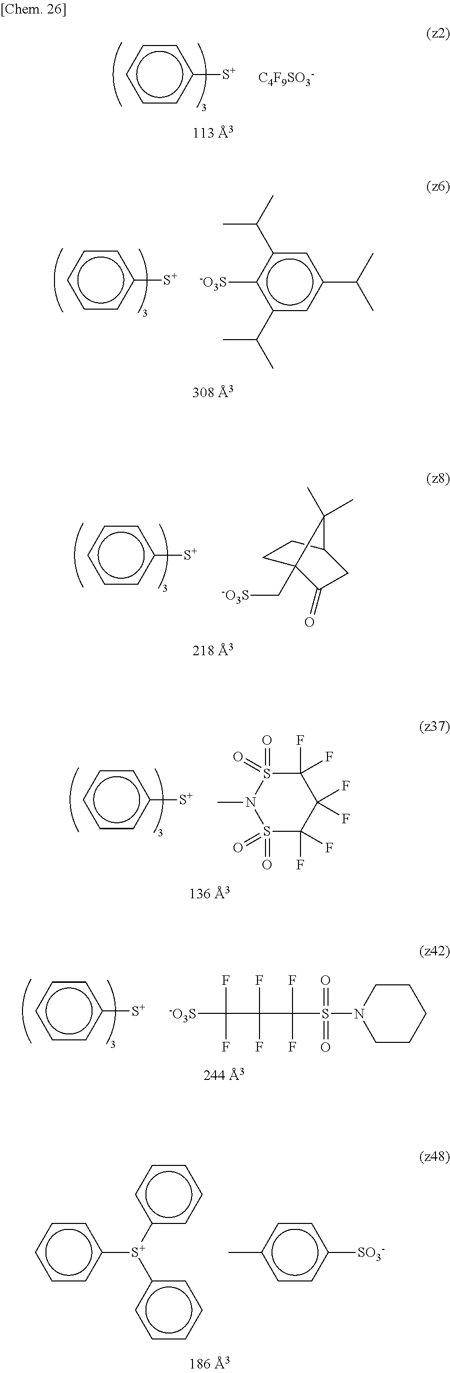

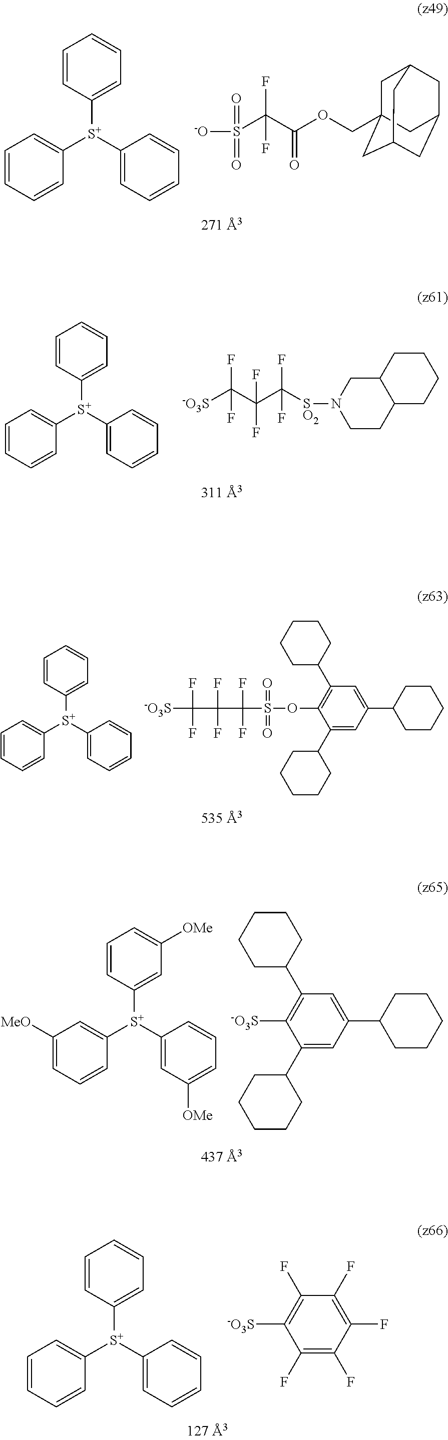

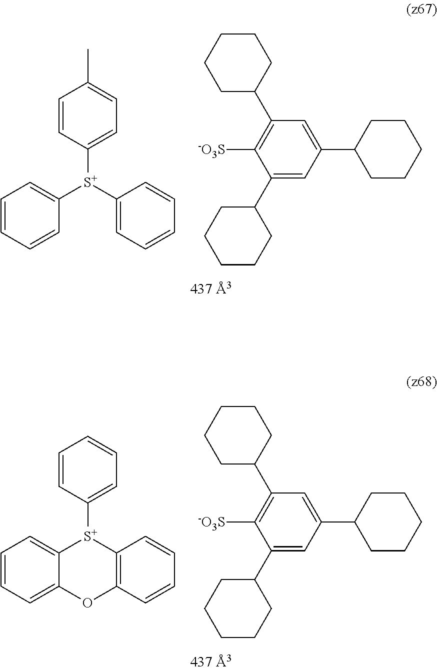

[Cross-Linking Agent (C)]

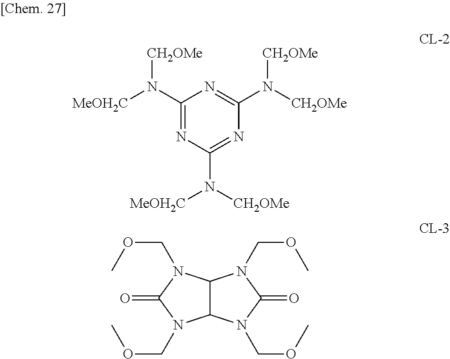

[Basic Compound]

B1: Tetrabutylammonium hydroxide

B2: Tri(n-octyl)amine

B3: 2,4,5-Triphenylimidazole

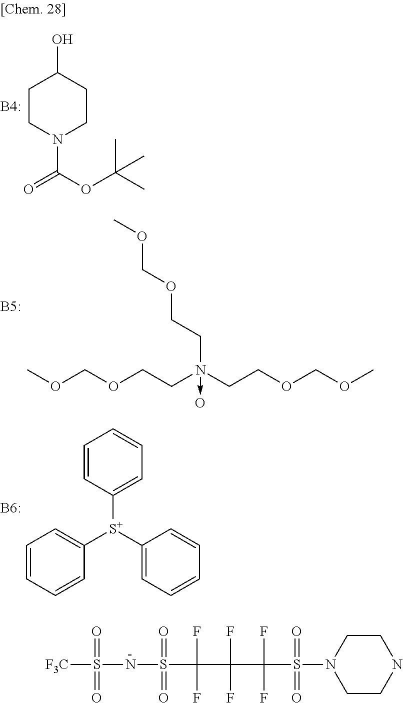

[Solvent]

S1: Propylene glycol monomethyl ether acetate (1-methoxy-2-acetoxypropane)

S2: Propylene glycol monomethyl ether (1-methoxy-2-propanol)

S3: 2-Heptanone

S4: Ethyl lactate

S5: Cyclohexanone

S6: γ-Butyrolactone

S7: Propylene carbonate

The evaluation results are shown in Table 3.

TABLE 3
(electron beam exposure; negative type; alkali development)

| | | | Resolving | | | | |
|---|---|---|---|---|---|---|---|
| | | Sensitivity | power | | Pattern | LER | Dry etching |
| Example | Composition | (μC/cm²) | (nm) | Scum | shape | (nm) | resistance |
| 1E | N1 | 9.2 | 40 | A | Rectangular | 4.5 | Very |
| | | | | | | | satisfactory |
| 2E | N2 | 9.1 | 40 | A | Rectangular | 4.5 | Very |
| | | | | | | | satisfactory |
| 3E | N3 | 9.3 | 40 | A | Rectangular | 4.5 | Very |
| | | | | | | | satisfactory |
| 4E | N4 | 9.2 | 40 | A | Rectangular | 4.5 | Satisfactory |
| 5E | N5 | 9.2 | 40 | A | Rectangular | 4.5 | Satisfactory |
| 6E | N6 | 10.3 | 40 | A | Rectangular | 4.5 | Very |
| | | | | | | | satisfactory |
| 7E | N7 | 10.4 | 40 | A | Rectangular | 4.5 | Very |
| | | | | | | | satisfactory |
| 8E | N8 | 9.2 | 40 | A | Rectangular | 4.5 | Very |
| | | | | | | | satisfactory |
| 9E | N9 | 9.5 | 40 | A | Rectangular | 4.5 | Very |
| | | | | | | | satisfactory |
| 10E | N10 | 10.3 | 40 | A | Rectangular | 4.5 | Very |
| | | | | | | | satisfactory |
| 11E | N11 | 9.2 | 40 | A | Rectangular | 4.5 | Very |
| | | | | | | | satisfactory |
| 12E | N12 | 9.1 | 40 | A | Rectangular | 4.5 | Very |
| | | | | | | | satisfactory |
| 13E | N13 | 9.3 | 45 | A | Rectangular | 4.5 | Very |
| | | | | | | | satisfactory |
| 14E | N14 | 9.2 | 45 | A | Rectangular | 4.5 | Very |
| | | | | | | | satisfactory |
| 15E | N15 | 9.2 | 40 | A | Rectangular | 5.0 | Very |
| | | | | | | | satisfactory |
| 16E | N16 | 9.2 | 45 | B | Slight | 5.0 | Very |
| | | | | | inverse taper | | satisfactory |
| 17E | N17 | 9.1 | 40 | B | Rectangular | 5.0 | Very |
| | | | | | | | satisfactory |
| 18E | N18 | 9.2 | 45 | B | Slight | 4.5 | Very |
| | | | | | inverse taper | | satisfactory |
| 19E | N19 | 9.1 | 45 | A | Rectangular | 5.0 | Very |
| | | | | | | | satisfactory |
| 20E | N20 | 9.3 | 45 | A | Rectangular | 4.5 | Very |
| | | | | | | | satisfactory |
| 21E | N21 | 9.2 | 40 | A | Rectangular | 4.5 | Very |
| | | | | | | | satisfactory |
| 22E | N22 | 9.2 | 40 | A | Rectangular | 4.5 | Very |
| | | | | | | | satisfactory |
| 23E | N23 | 9.2 | 40 | A | Rectangular | 4.5 | Very |
| | | | | | | | satisfactory |
| 24E | N24 | 9.3 | 40 | A | Rectangular | 4.5 | Satisfactory |
| Comparative | Comparative | 10.7 | 55 | C | Slight | 5.5 | Poor |
| Example 1E | composition | | | | inverse taper | | |
| | N1 | | | | | | |
| Comparative | Comparative | 10.6 | 55 | C | Slight | 5.5 | Poor |
| Example 2E | composition | | | | inverse taper | | |
| | N2 | | | | | | |
| Comparative | Comparative | 10.5 | 55 | C | Slight | 5.5 | Poor |
| Example 3E | composition | | | | inverse taper | | |
| | N3 | | | | | | |

From the results shown in Table 3, it is understood that the composition according to the present invention is excellent in sensitivity, resolving power, reduction of scum, pattern shape, line edge roughness (LER) and dry etching resistance.

(II) Examples of Negative Chemical Amplification Resist (EUV and Alkali Development)

### [Examples 1F to 6F and Comparative Examples 1F to 3F]

### Preparation of Resist Solution

The negative resist compositions shown in the following Table 4 were filtered through a polytetrafluoroethylene filter having a pore size of 0.04 μm, and thus negative resist solutions were prepared.

(Resist Evaluation)

Each of the negative resist solutions thus prepared was uniformly applied on a silicon substrate that had been subjected to a hexamethyldisilazane treatment, by using a spin coater. The system was heated and dried on a hot plate at 100° C. for 60 seconds, and thus a resist film having a thickness of 0.05 μm was formed.

The resist film thus obtained was evaluated for sensitivity, resolving power, scum, pattern shape, line edge roughness (LER) and dry etching resistance by the methods described below.

[Sensitivity]

The resist film thus obtained was exposed through a reflection type mask having a 1:1 line-and-space pattern having a line width of 100 nm, by using EUV light (wavelength: 13 nm) while changing the amount of exposure by 0.1 mJ/cm² over the range of 0 to 20.0 mJ/cm², and then the resist film was baked for 90 seconds at 110° C. Thereafter, the resist pattern was developed by using a 2.38 mass % aqueous solution of tetramethylammonium hydroxide (TMAH).

The amount of exposure which reproduced the line-and-space (L/S=1/1) mask pattern with a line width of 100 nm was designated as sensitivity. A smaller value of this amount of exposure indicates higher sensitivity.

[Resolving Power]

The limit resolving power (minimum line width at which lines and spaces (line:space=1:1) are separated and resolved) at the amount of exposure exhibiting the sensitivity described above was designated as the resolving power (nm).

[Pattern Shape]

The cross-sectional shape of a line pattern (L/S=1/1) having a line width of 100 nm at the amount of exposure exhibiting the sensitivity described above, was observed by using a scanning electron microscope (S-4300 manufactured by Hitachi, Ltd.). In regard to the cross-sectional shape of the line pattern, a sample in which the ratio represented by [line width at the top (surface area) of the line pattern/line width in the middle of the line pattern (height position at a half of the line pattern height)] is 1.5 or more was designated as “inverse taper”; a sample in which the ratio is greater than or equal to 1.2 and less than 1.5 was designated as “slightly inverse taper”; and a sample in which the ratio is less than 1.2 was designated as “rectangular.” Thus, an evaluation was performed.

[Scum Evaluation]

A line pattern was formed by the same method as described in section [Pattern shape]. Thereafter, a cross-section SEM was obtained by using a scanning electron microscope S4800 (manufactured by Hitachi High Technologies Corp.), and the presence of scum in the space area was observed and evaluated as follows.

C: Scum is observed, and patterns are partially connected to each other.

B: Scum is observed, but patterns are not connected to each other.

A: No scum is observed.

[Line edge roughness (LER)]

A line pattern (L/S=1/1) having a line width of 100 nm was formed with the amount of exposure exhibiting the sensitivity described above. At any arbitrary 30 points included in 50 μm along the length direction, the distance from a reference line at which an edge should exist was measured by using a scanning electron microscope (S-9220 manufactured by Hitachi, Ltd.). The standard deviation of this distance was determined, and 3σ was calculated. A smaller value indicates satisfactory performance.

[Dry Etching Resistance]

A resist film on which a resist pattern having a line width of 100 nm (line:space=1:1) was formed at the amount of exposure exhibiting the sensitivity described above, was subjected to dry etching for 15 seconds wity Ar/C₄F₆/O₂ gas (gas mixture at a volume ratio of 100/4/2) by using HITACHI U-621. Thereafter, the resist residual film ratio was measured and was used as an indicator for dry etching resistance.

Very satisfactory: a residual film ratio of 95% or greater

Satisfactory: a residual film ratio of greater than or equal to 90% and less than 95%

Poor: a residual film ratio of less than 90%

Evaluation results obtained as described above are shown in Table 4.

TABLE 4
(EUV exposure; negative type; alkali development)

| | | | Resolving | | | | |
|---|---|---|---|---|---|---|---|
| | | Sensitivity | power | | | LER | Dry etching |
| Example | Composition | (mJ/cm²) | (nm) | Scum | Pattern shape | (nm) | resistance |
| 1F | N1 | 12.5 | 40 | A | Rectangular | 4.5 | Very |
| | | | | | | | satisfactory |
| 2F | N2 | 12.6 | 40 | A | Rectangular | 4.5 | Very |
| | | | | | | | satisfactory |
| 3F | N3 | 12.3 | 40 | A | Rectangular | 4.5 | Very |
| | | | | | | | satisfactory |
| 4F | N6 | 13.5 | 40 | A | Rectangular | 4.5 | Very |
| | | | | | | | satisfactory |
| 5F | N7 | 13.5 | 40 | A | Rectangular | 4.5 | Very |
| | | | | | | | satisfactory |
| 6F | N8 | 13.4 | 40 | A | Rectangular | 4.5 | Very |
| | | | | | | | satisfactory |
| Comparative | Comparative | 13.8 | 55 | C | Slight inverse | 5.5 | Poor |
| Example 1F | composition | | | | taper | | |
| | N1 | | | | | | |
| Comparative | Comparative | 13.8 | 55 | C | Slight inverse | 5.5 | Poor |
| Example 2F | composition | | | | taper | | |
| | N2 | | | | | | |
| Comparative | Comparative | 13.4 | 55 | C | Slight inverse | 5.5 | Poor |
| Example 3F | composition | | | | taper | | |
| | N3 | | | | | | |

From the results shown in Table 4, it is understood that the composition according to the present invention is excellent in sensitivity, resolving power, scum reduction, pattern shape, line edge roughness (LER), and dry etching resistance, even under exposure to EUV.

This application claims priority under 35 U.S.C. §119 of Japanese Patent application JP 2011-219472, filed on Oct. 3, 2011, the entire contents of which are hereby incorporated by reference.

What is claimed is:

1. A negative chemical amplification resist composition comprising:
(A) a polymer compound having a repeating unit (P) represented by the following formula (I) which is stable in acids and alkalis, and a repeating unit (Q) having a phenolic hydroxyl group;
(B) a compound capable of generating an acid when irradiated with actinic rays or radiation; and
(C) a cross-linking agent: 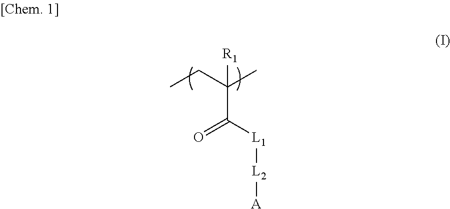
wherein in the formula (I), R₁ represents a hydrogen atom or a methyl group;
L₁ represents an oxygen atom or —NH—;
L₂ represents a single bond or an alkylene group; and
A represents a polycyclic hydrocarbon group.

2. The negative chemical amplification resist composition according to claim 1, wherein in the formula (I), A represents an alicyclic polycyclic hydrocarbon group.

3. The negative chemical amplification resist composition according to claim 1, which is for use under exposure to electron beam or extreme ultraviolet rays.

4. The negative chemical amplification resist composition according to claim 1, wherein the repeating unit (Q) having a phenolic hydroxyl group is a repeating unit represented by the following formula (IV): 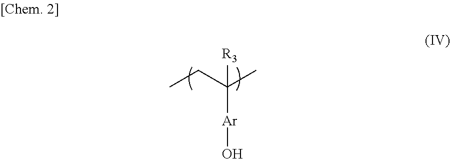
wherein in the formula (IV), R₃ represents a hydrogen atom or a methyl group; and
Ar represents an aromatic ring.

5. The negative chemical amplification resist composition according to claim 2, wherein the repeating unit (Q) having a phenolic hydroxyl group is a repeating unit represented by the following formula (IV): 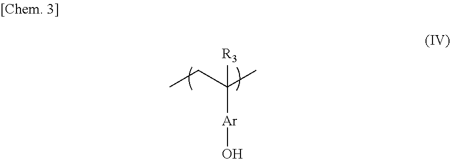
wherein in the formula (IV), R₃ represents a hydrogen atom or a methyl group; and
Ar represents an aromatic ring.

6. The negative chemical amplification resist composition according to claim 1, wherein the repeating unit (P) represented by the formula (I) is a repeating unit represented by the following formula (II): 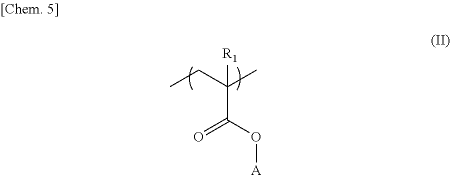
wherein in the formula (II), R₁ and A have the same meanings as R₁ and A defined in the formula (I).

7. The negative chemical amplification resist composition according to claim 2, wherein the repeating unit (P) represented by the formula (I) is a repeating unit represented by the following formula (II): 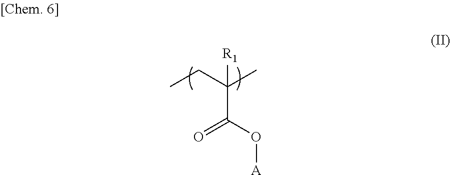
wherein in the formula (II), R₁ and A have the same meanings as R₁ and A defined in the formula (I).

8. The negative chemical amplification resist composition according to claim 1, wherein the cross-linking agent (C) is a compound having two or more hydroxymethyl groups or alkoxymethyl groups in the molecule.

9. The negative chemical amplification resist composition according to claim 1, wherein the acid generated from the compound (B) by the irradiation of actinic rays or radiation is an acid having a volume size of 130 Å³ or larger.

10. A resist film formed from the negative chemical amplification resist composition according to claim 1.

11. Resist-coated mask blanks comprising the resist film according to claim 10.

12. A method for forming a resist pattern comprising exposing the resist film according to claim 10, and developing the exposed film.

13. A method for forming a resist pattern comprising exposing the resist-coated mask blanks according to claim 11, and developing the exposed mask blanks.

14. The method for forming a resist pattern according to claim 12, wherein the exposure is carried out by using an electron beam or extreme ultraviolet rays.

15. The method for forming a resist pattern according to claim 13, wherein the exposure is carried out by using an electron beam or extreme ultraviolet rays.

16. A photomask obtained by exposing and developing the resist-coated mask blanks according to claim 11.
